(19) United States
(12) Patent Application Publication
(10) Pub. No.: US 2026/0129372 A1
(43) Pub. Date: May 7, 2026

(54) DRIVER UNIT AND HEADPHONE

(71) Applicant: FUJIFILM Corporation, Tokyo (JP)

(72) Inventor: Tetsu MIYOSHI, Minamiashigara-shi (JP)

(73) Assignee: FUJIFILM Corporation, Tokyo (JP)

(21) Appl. No.: 19/434,883

(22) Filed: Dec. 29, 2025

Related U.S. Application Data
(63) Continuation of application No. PCT/JP2024/023163, filed on Jun. 26, 2024.

(30) Foreign Application Priority Data
Jun. 30, 2023 (JP) 2023-108023
Jun. 25, 2024 (JP) 2024-102098

(51) Int. Cl. H04R 17/00; H04R 1/02; H04R 1/28; H10N 30/20; H10N 30/80; H10N 30/85; H10N 30/857; H10N 30/87; H10N 30/88

(52) U.S. Cl. CPC H04R 17/005; H04R 1/025; H04R 1/288; H10N 30/2048; H10N 30/804; H10N 30/852; H10N 30/857; H10N 30/872; H10N 30/883; H04R 2217/01

(57) ABSTRACT

Provided are a driver unit of a headphone, in which, in a case where a driver unit including a piezoelectric film having a formed curved portion is applied to the headphone, deformation of the curved portion of the piezoelectric film in a case of wearing the headphone can be suppressed, and deterioration in sound quality can be suppressed; and a headphone. The driver unit includes a piezoelectric film which has a piezoelectric layer consisting of a polymer-based piezoelectric composite material containing piezoelectric particles in a matrix containing a polymer material and electrode layers provided on both surfaces of the piezoelectric layer, and a perforated plate having at least one through-hole, in which the piezoelectric film has a curved portion which is formed to protrude to one main surface side and to be recessed to the other main surface side, the perforated plate is laminated on a concave surface side of the curved portion of the piezoelectric film, and in the through-hole, a first air chamber defined by the concave surface of the piezoelectric film and the perforated plate communicates with an outside.

### CROSS-REFERENCE TO RELATED APPLICATIONS

This application is a Continuation of PCT International Application No. PCT/JP2024/023163 filed on Jun. 26, 2024, which claims priority under 35 U.S.C. § 119 (a) to Japanese Patent Application No. 2023-108023 filed on Jun. 30, 2023 and Japanese Patent Application No. 2024-102098 filed on Jun. 25, 2024. The above applications are hereby expressly incorporated by reference, in their entirety, into the present application.

### BACKGROUND OF THE INVENTION

### 1. Field of the Invention

The present invention relates to a driver unit and a headphone using the driver unit.

### 2. Description of the Related Art

As a thin speaker, it has been proposed to use a piezoelectric film in which a piezoelectric layer is sandwiched between an electrode layer and a protective layer.

For example, WO2016/017632A discloses an electroacoustic conversion film (piezoelectric film) including a polymer-based piezoelectric composite material in which piezoelectric particles are dispersed in a viscoelastic matrix consisting of a polymer material having viscoelasticity at normal temperature, and a pair of electrode pairs laminated on both surfaces of the polymer-based piezoelectric composite material, in which the electroacoustic conversion film has one or more protrusions which are formed in a convex shape to protrude to one main surface side.

### SUMMARY OF THE INVENTION

The present inventor has studied adopting the piezoelectric film in a driver unit of a headphone. In a case of being used as the driver unit of a headphone, it is necessary to be small and light and to generate high-quality sound in a wide band. Therefore, the present inventor has considered that, in a case of adopting the piezoelectric film in the driver unit of the headphone, it is appropriate to use the piezoelectric film itself as a vibration plate, and to use a piezoelectric film having one or more protrusions (curved portions) which are formed in a convex shape to protrude to one main surface side, as a configuration in which the piezoelectric film can be made broadband with a vibration plate (piezoelectric film) which can be mounted on the headphone.

In the headphone, it is known that a sound pressure in a low-frequency range is improved by bringing an ear and an ear pad into close contact with each other to put an internal air chamber (inside a housing) into a substantially sealed state, that is, by using a so-called sealed type or quasi-sealed type.

However, according to the studies of the present inventor, in a configuration in which a driver unit including a piezoelectric film having a curved portion which is formed in a convex shape to protrude to one main surface side is incorporated into the headphone, in a case where the ear and the ear pad are brought into close contact with each other to put the inside of the housing into a substantially sealed state, resonance or the like in a high-frequency range occurs in the housing, and thus a variation (also referred to as a ripple, a peak, or a dip on a frequency characteristic) occurs in the frequency characteristic in the high-frequency range, and a flat frequency characteristic is not obtained, which is a problem.

An object of the present invention is to solve such a problem of the related art, and to provide a driver unit and a headphone in which, in a case where a driver unit including a piezoelectric film having a formed curved portion is applied to the headphone, a frequency characteristic can be improved.

In order to solve the above-described problems, the present invention has the following configuration.

[1] A driver unit comprising:
a piezoelectric film which has a piezoelectric layer consisting of a polymer-based piezoelectric composite material containing piezoelectric particles in a matrix containing a polymer material and electrode layers provided on both surfaces of the piezoelectric layer; and
a plate-shaped perforated plate having at least one through-hole,
in which the piezoelectric film has a curved portion which is formed to protrude to one main surface side and to be recessed to the other main surface side,
the perforated plate is laminated on a concave surface side of the curved portion of the piezoelectric film, and
in the through-hole, a first air chamber defined by the concave surface of the piezoelectric film and the perforated plate communicates with an outside.

[2] The driver unit according to [1],
in which a proportion of a total area of the through-holes to an area of the curved portion of the piezoelectric film in a plan view is 3% to 70%.

[3] The driver unit according to [1] or [2], further comprising:
an acoustic absorption layer consisting of a porous material which is disposed to cover the through-hole on a surface of the perforated plate opposite to the piezoelectric film.

[4] The driver unit according to any one of [1] to [3],
in which a shape formed by a boundary line of the curved portion of the piezoelectric film is circular.

[5] The driver unit according to any one of [1] to [4], further comprising:
a series resistor connected between the electrode layers of the piezoelectric film and a signal source which drives the piezoelectric film.

[6] A headphone comprising:
the driver unit according to any one of [1] to [5];
a housing which has an opening portion and accommodates the driver unit; and an ear pad which is disposed on an opening portion side of the housing.

[7] The headphone according to [6],
in which a second air chamber defined by the driver unit and the housing communicates with an outside.

[8] The headphone according to [6] or [7],
in which the housing is disposed on the concave surface side of the piezoelectric film of the driver unit.

[9] The headphone according to [6], further comprising:
a protector ring which is disposed to be in contact with the ear pad between the driver unit and the ear pad,
in which the protector ring has an opening portion which penetrates in a direction perpendicular to a surface in contact with the ear pad,
the protector ring is in contact with a region of 30% or more of a total area of the ear pad in a case of being viewed in the direction perpendicular to the surface in contact with the ear pad, and
a shortest distance between the protector ring and the piezoelectric film of the driver unit is 0.3 mm or more.

According to the present invention, it is possible to provide a driver unit and a headphone in which, in a case where a driver unit including a piezoelectric film having a formed curved portion is applied to the headphone, a frequency characteristic can be improved.

### BRIEF DESCRIPTION OF THE DRAWINGS

FIG. 1 is a cross-sectional view conceptually showing an example of the headphone according to the embodiment of the present invention, including the driver unit according to the embodiment of the present invention.

FIG. 2 is an exploded perspective view of the driver unit shown in FIG. 1.

FIG. 3 is a perspective view of a piezoelectric film included in the driver unit shown in FIG. 1.

FIG. 4 is a cross-sectional view of the piezoelectric film shown in FIG. 3.

FIG. 5 is a plan view of the piezoelectric film shown in FIG. 3.

FIG. 6 is a plan view conceptually showing another example of the piezoelectric film.

FIG. 7 is a view for describing an action of the driver unit according to the embodiment of the present invention.

FIG. 8 is a view conceptually showing another example of the headphone according to the embodiment of the present invention, including the driver unit according to the embodiment of the present invention.

FIG. 9 is a view conceptually showing another example of the driver unit according to the embodiment of the present invention.

FIG. 10 is a cross-sectional view for describing an example of a configuration of the piezoelectric film.

FIG. 11 is a conceptual view for describing an example of a production method of the piezoelectric film.

FIG. 12 is a conceptual view for describing an example of a production method of the piezoelectric film.

FIG. 13 is a conceptual view for describing an example of a production method of the piezoelectric film.

FIG. 14 is a block diagram conceptually showing an example of a circuit which drives the driver unit.

FIG. 15 is a graph showing a relationship between a frequency and a sound pressure.

FIG. 16 is a graph showing a relationship between a frequency and a sound pressure.

FIG. 17 is a graph showing a relationship between a frequency and a sound pressure.

FIG. 18 is a graph showing a relationship between a frequency and a sound pressure.

FIG. 19 is a conceptual view for describing an action of a headphone including a driver unit of Comparative Example.

FIG. 20 is a view conceptually showing another example of the piezoelectric film included in the driver unit according to the embodiment of the present invention.

FIG. 21 is a partially enlarged cross-sectional view of FIG. 20.

FIG. 22 is a cross-sectional view conceptually showing another example of the headphone according to the embodiment of the present invention, including the driver unit according to the embodiment of the present invention.

FIG. 23 is a view conceptually showing a state in which the example of the headphone according to the embodiment of the present invention is pressed against an artificial ear.

FIG. 24 is a view conceptually showing a state in which another example of the headphone according to the embodiment of the present invention is pressed against an artificial ear.

FIG. 25 is a view for describing an area proportion of a surface in contact with the protector ring and the ear pad.

FIG. 26 is a cross-sectional view conceptually showing still another example of the headphone according to the embodiment of the present invention, including the driver unit according to the embodiment of the present invention.

FIG. 27 is a graph showing a relationship between a frequency and a sound pressure.

FIG. 28 is a graph showing a relationship between a frequency and a sound pressure.

FIG. 29 is a graph showing a relationship between a frequency and a sound pressure.

### DESCRIPTION OF THE PREFERRED EMBODIMENTS

Hereinafter, the driver unit and the headphone according to the present invention will be described in detail based on suitable embodiments shown in the accompanying drawings.

Although configuration requirements to be described below are described based on representative embodiments of the present invention, the present invention is not limited to the embodiments.

Any numerical range expressed using “to” in the present specification refers to a range including the numerical values before and after the “to” as a lower limit value and an upper limit value, respectively.

### [Driver Unit and Headphone]

The driver unit according to the embodiment of the present invention includes:
a piezoelectric film which has a piezoelectric layer consisting of a polymer-based piezoelectric composite material containing piezoelectric particles in a matrix containing a polymer material and electrode layers provided on both surfaces of the piezoelectric layer; and
a perforated plate having at least one through-hole,
in which the piezoelectric film has a curved portion which is formed to protrude to one main surface side and to be recessed to the other main surface side,
the perforated plate is laminated on a concave surface side of the curved portion of the piezoelectric film, and
in the through-hole, a first air chamber defined by the concave surface of the piezoelectric film and the perforated plate communicates with an outside.

The headphone according to the embodiment of the present invention includes:
the above-described driver unit;
a housing which accommodates the driver unit in an opening portion; and
an ear pad which is disposed on a surface side of the driver unit opposite to the housing.

### <Driver Unit>

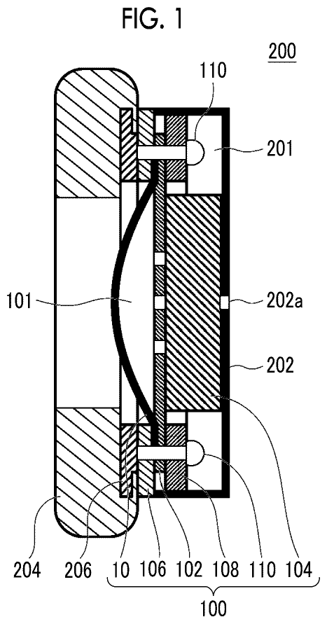

FIG. 1 is a cross-sectional view conceptually showing an example of the headphone according to the embodiment of the present invention, including an example of the driver unit according to the embodiment of the present invention.

A headphone 200 shown in FIG. 1 includes a driver unit 100, a housing 202, an ear pad 204, and an ear pad locking member 206.

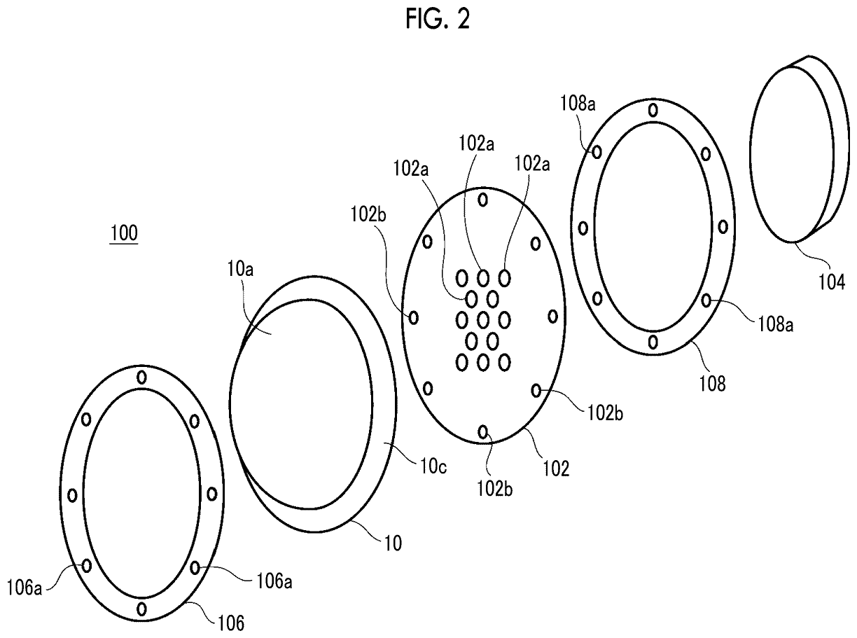

FIG. 2 is an exploded perspective view of the driver unit 100.

As shown in FIGS. 1 and 2, a driver unit 100 includes a holding member 106, a piezoelectric film 10, a perforated plate 102, a holding member 108, a porous material 104, and a fastening member 110.

The piezoelectric film 10 is a piezoelectric film which has a piezoelectric layer consisting of a polymer-based piezoelectric composite material containing piezoelectric particles in a matrix containing a polymer material and electrode layers provided on both surfaces of the piezoelectric layer, in which the piezoelectric film has a curved portion 10a which is formed to protrude to one main surface side and to be recessed to the other main surface side.

Details of each layer constituting the piezoelectric film 10 will be described later.

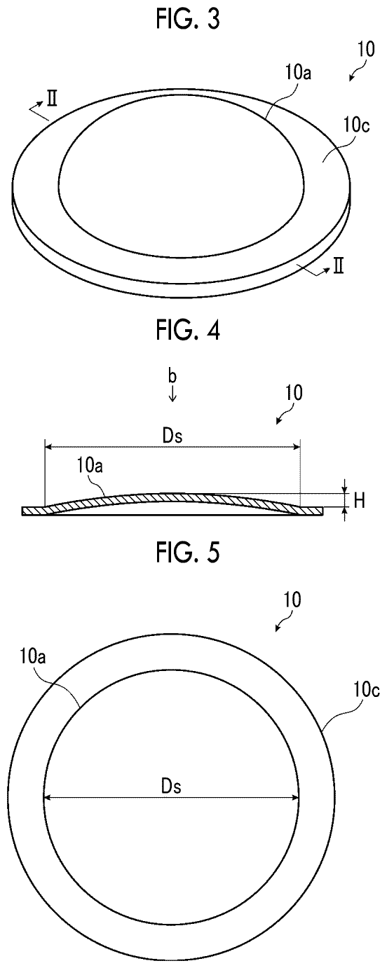

FIG. 3 is a perspective view of the piezoelectric film 10. FIG. 4 is a cross-sectional view of the piezoelectric film 10. FIG. 5 is a plan view of the piezoelectric film 10. The plan view is a view of the piezoelectric film 10 as viewed from a direction perpendicular to a main surface of a flat portion (a region in which the curved portion 10a is not formed), and is a view as viewed from an arrow b direction in FIG. 4. In addition, in the present invention, the main surface is a maximum surface of a sheet-like material.

In the example shown in FIGS. 3 to 5, the piezoelectric film 10 has an outer shape which is substantially circular in a plan view, and has the curved portion 10a which is formed to protrude to one main surface side with a diameter Ds and a height H at a substantially central portion thereof (a convex curved portion). In addition, the curved portion 10a is recessed and formed in a concave shape as viewed from the main surface opposite to the main surface on a side where the curved portion 10a protrudes. That is, the piezoelectric film 10 can also be said to be a film in which a recess portion is formed.

In addition, in the example shown in FIGS. 3 to 5, a shape of the curved portion 10a in a plan view is substantially circular. That is, a shape formed by a boundary line of the curved portion 10a is circular. In addition, in the example shown in FIGS. 3 to 5, the shape of the curved portion 10a is a shape consisting of a part of a sphere (substantially spherical cap shape).

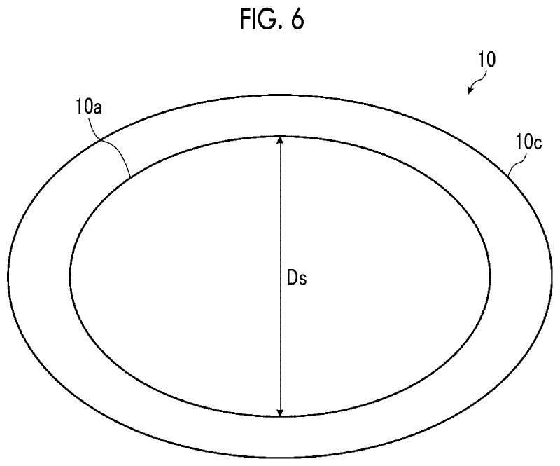

The shape of the curved portion 10a is not particularly limited, and is preferably a part of a sphere or a part of a rotational ellipsoid. In addition, the shape of the curved portion in a plan view is not particularly limited, and may be a substantially elliptical shape as shown in FIG. 6.

In addition, as shown in FIG. 4, a shape of the curved portion as viewed in a cross section perpendicular to the main surface of the piezoelectric film is preferably curved as a whole, but it is not limited thereto, and may have a flat portion in a part thereof. For example, the curved portion may have a flat top.

In addition, in a case where the curved portion 10a as viewed in the cross section perpendicular to the main surface of the piezoelectric film 10 is an arc, and a straight line connecting both end points of the arc is a chord, an angle θ between a main surface of the holding member 106 and the chord does not need to be a right angle (90°). For example, in a case where a chord length is 60 mm and a distance from a midpoint of the arc to a midpoint of the chord, that is, a sagitta is 5 mm, an angle between tangents at both end points of the arc and the chord is known as a tangent-secant theorem to be equal to a circumference angle of the arc, and the circumference angle in this case is 18.9°. That is, in a case where the angle θ between the main surface of the holding member 106 and the chord is 18.9° or more, interference between the curved portion 10a of the piezoelectric film 10 and the holding member 106 can be avoided.

In a case where a voltage is applied to the electrode layers (electrode pair) which sandwich the piezoelectric layer of the piezoelectric film 10, the piezoelectric layer is driven, and expands and contracts in response to the applied voltage. In this case, in the curved portion 10a, expansion and contraction in a plane direction is converted into vibration in a direction perpendicular to the plane, and thus an electric signal is converted into vibration (sound).

The diameter Ds and the height H of the curved portion 10a of the piezoelectric film 10 are not particularly limited, and may be appropriately set according to a size of the housing of the headphone 200 in which the driver unit 100 is incorporated, a size of the ear pad, and the like. From the viewpoint of improving a sound pressure in an audible range, the diameter Ds of the curved portion 10a is preferably 30 mm to 80 mm, more preferably 40 mm to 70 mm, and still more preferably 50 mm to 60 mm. In addition, the height H of the curved portion 10a is preferably 1 mm to 10 mm, more preferably 2 mm to 7 mm, and still more preferably 3 mm to 5 mm. Abnormal deformation of the curved portion 10a, which will be described later, is less likely to occur as the diameter Ds is smaller, but since the driver unit 100 according to the embodiment of the present invention can suitably suppress the abnormal deformation of the curved portion 10a, from the viewpoint of improving the sound pressure in the audible range, the diameter Ds is preferably within the above-described range.

In addition, from the viewpoint of efficiently converting the expansion and contraction of the piezoelectric film in the plane direction in a case where the voltage is applied into the vibration in the direction perpendicular to the plane to improve the sound pressure, a ratio H/Ds of the diameter Ds to the height H of the curved portion 10a preferably satisfies 0<H/Ds≤0.15. The upper limit value of the ratio H/Ds is preferably 0.1 or less, more preferably 0.075 or less, and still more preferably 0.05 or less. In addition, the lower limit value thereof is preferably 0.003 or more, and more preferably 0.005 or more.

The perforated plate 102 is laminated on the concave surface side of the curved portion 10a of the piezoelectric film 10. In the example shown in the drawing, the perforated plate 102 is in direct contact with the concave surface side of the piezoelectric film 10.

The perforated plate 102 is disposed on the concave surface side of the curved portion 10a of the piezoelectric film 10 to define a first air chamber 101 surrounded with the concave surface.

One or more through-holes 102a which communicate the first air chamber 101 with the outside are formed at a substantially central portion of the perforated plate 102. In the example shown in the drawing, 13 through-holes 102a are arranged in a staggered manner. In addition, a shape of an opening cross section of each through-hole 102a is substantially circular.

The number, the size, and the like of the through-holes 102a formed in the perforated plate 102 are not particularly limited. In addition, in the example shown in the drawing, diameters of all the through-holes 102a are the same, but the present invention is not limited thereto, and the perforated plate 102 may have through-holes 102a having different diameters. In addition, a proportion of the total area of the through-holes 102a to an area of a vibration region of the piezoelectric film 10, that is, an area of the curved portion 10a in a plan view is preferably 3% to 70%. This point will be described later.

The disposition of the through-holes 102a is not particularly limited as long as the first air chamber 101 can communicate with the outside. In addition, in a case where the plurality of the through-holes 102a are provided, a disposition pattern of the plurality of the through-holes 102a is not particularly limited.

The perforated plate 102 has an insertion hole 102b for inserting the fastening member 110 described later, in a vicinity of an end portion in a plan view. The number, the disposition, and the like of the insertion hole 102b in the perforated plate 102 may be set according to the number, the disposition, and the like of a screw hole 106a in the holding member 106. In the example shown in the drawing, eight insertion holes 102b are provided at regular intervals in a circumferential direction. The number and the disposition of the insertion hole 102b are not limited thereto. In addition, the perforated plate 102 may be configured to be simply sandwiched between the holding member 106 and the holding member 108 without having the insertion hole 102b, with an outer diameter which does not overlap a position of the screw hole 106a in the holding member 106.

A thickness of the perforated plate 102 is not particularly limited. From the viewpoint of size reduction, weight reduction, and the like of the driver unit 100, the thickness of the perforated plate 102 is preferably 0.1 mm to 5 mm, more preferably 0.2 mm to 3 mm, and still more preferably 0.3 mm to 1 mm.

As the perforated plate 102, various plate-shaped materials (sheet-like materials, films) can be used.

Examples of the perforated plate 102 include resin films made of polyethylene terephthalate (PET), polypropylene (PP), polystyrene (PS), polycarbonate (PC), polyphenylene sulfide (PPS), polymethylmethacrylate (PMMA), and polyetherimide (PEI), polyimide (PI), polyethylene naphthalate (PEN), triacetyl cellulose (TAC), cyclic olefin-based resins, or the like; foamed plastic made of foamed polystyrene, foamed styrene, foamed polyethylene, or the like; veneer boards, cork boards, leathers such as cowhide, various kinds of paperboards such as carbon sheets and Japanese paper, various kinds of corrugated cardboard materials obtained by bonding, to one or both surfaces of a corrugated paperboard, other paperboards; and various kinds of metals such as stainless steel, aluminum, copper, and nickel, and a thin film metal consisting of various kinds of alloys. In addition, the perforated plate 102 may be a composite material in which film-like materials consisting of these materials are bonded to each other, and various surface treatments such as an alumite treatment may be performed.

The holding member 106 and the holding member 108 are members for holding the piezoelectric film 10 and the perforated plate 102 in a laminated state. The holding member 106 and the holding member 108 are annular (ring-shaped) plate members. The holding member 106 is disposed on the piezoelectric film 10 side and the holding member 108 is disposed on the perforated plate 102 side to sandwich the piezoelectric film 10 and the perforated plate 102, thereby holding the piezoelectric film 10 and the perforated plate 102 in a laminated state.

An opening portion of the holding member 106 has a diameter larger than a diameter of the curved portion 10a of the piezoelectric film 10 in a plan view, and has a size into which the curved portion 10a (convex portion) is inserted. The holding member 106 abuts against at least a part of an edge portion of the piezoelectric film 10.

The holding member 106 has a screw hole 106a for screwing with the fastening member 110 described later, in a vicinity of an end portion in a plan view. The number, the disposition, and the like of the screw hole 106a in the holding member 106 may be appropriately set. In the example shown in the drawing, eight screw holes 106a are provided at regular intervals in a circumferential direction. The number and the disposition of the screw hole 106a are not limited thereto.

An opening portion of the holding member 108 has a size which does not block the through-holes 102a of the perforated plate 102. In addition, the holding member 108 has an insertion hole 108a for inserting the fastening member 110 described later, in a vicinity of an end portion in a plan view. The number, the disposition, and the like of the insertion hole 108a in the holding member 108 may be set according to the number, the disposition, and the like of the screw hole 106a in the holding member 106. In the example shown in the drawing, eight insertion holes 108a are provided at regular intervals in a circumferential direction. The number and the disposition of the insertion hole 108a are also not limited thereto.

As shown in FIG. 1, a screw, which is the fastening member 110, is inserted into the insertion hole 108a of the holding member 108 and the insertion hole 102b of the perforated plate 102 from the holding member 108 side, and is screwed into the screw hole 106a of the holding member 106, whereby the holding member 106 and the holding member 108 sandwich and hold the piezoelectric film 10 and the perforated plate 102.

In the example shown in the drawing, the holding member 106 and the holding member 108 have substantially circular outer shapes in a plan view and substantially circular opening portions; but the present invention is not limited thereto, and various shapes can be adopted as long as the piezoelectric film 10 and the perforated plate 102 can be appropriately sandwiched. In addition, the holding member 106 and the holding member 108 may have different shapes. For example, the holding member 106 and the holding member 108 may have different diameters of the opening portions or different thicknesses.

The thicknesses of the holding member 106 and the holding member 108 are preferably 0.3 mm to 5 mm, more preferably 0.5 mm to 3 mm, and still more preferably 1 mm to 2 mm.

As a forming material of the holding member 106 and the holding member 108, the same material as the material of the perforated plate 102 described above can be used.

In the example shown in the drawing, the holding member 106 and the holding member 108 are configured to be fixed by the fastening member (screw) 110 in a state of sandwiching the piezoelectric film 10 and the perforated plate 102, but the present invention is not limited thereto. As a method of fixing the holding member 106 and the holding member 108, various known methods such as a method using a bolt and a nut and a method using a jig for fixing can be used. In addition, the holding member 108 on the perforated plate 102 side may not be provided, and the perforated plate 102 may also have a function of the holding member. That is, the perforated plate 102 and the holding member 108 may be integrally formed.

The porous material 104 is disposed on the surface of the perforated plate 102 opposite to the piezoelectric film 10 to cover the through-holes 102a. In the example shown in the drawing, since the perforated plate 102 has a plurality of through-holes 102a, the porous material 104 is disposed to cover the plurality of through-holes 102a. The porous material 104 corresponds to an acoustic absorption layer in the present invention.

The porous material 104 is a member in which a large number of small air holes or voids are formed inside, and thus gas can be communicated. The porous material 104 acts as an air flow resistance between the first air chamber 101 and a second air chamber, which are communicated with each other by the through-hole 102a of the perforated plate 102, and has a function as a pressure adjusting valve. This point will be described later.

The porous material 104 is not particularly limited, and known porous materials can be appropriately used. For example, various known porous materials such as a foaming body and a foamed material (foamed urethane foam (for example, Calmflex F manufactured by Inoac Corporation, Urethane foam manufactured by Hikari Co., Ltd., and the like), soft urethane foam, a ceramic particle sintered material, a phenol foam, a melamine foam, a polyamide foam, and the like) can be used. In addition, a nonwoven fabric or a woven fabric can also be used as the porous material. As the nonwoven fabric, various known nonwoven fabrics such as a nonwoven fabric-based sound absorbing material (a microfiber nonwoven fabric (for example, Thinsulate manufactured by 3M Company), a polyester nonwoven fabric (for example, White Kyuon manufactured by TOKYO Bouon, QonPET manufactured by Bridgestone KBG Co., Ltd., and Micromat manufactured by Softpren Co., Ltd.; these products are also provided in a two-layer configuration of a thin surface nonwoven fabric having a large density and a back nonwoven fabric having a small density), a plastic nonwoven fabric such as an acrylic fiber nonwoven fabric, a natural fiber nonwoven fabric such as wool and felt, a metal nonwoven fabric, and a glass nonwoven fabric), and other materials including minute air (glass wool, rock wool, and a nanofiber-based fiber acoustic absorption material (silica nanofiber and acrylic nanofiber (for example, XAI manufactured by Mitsubishi Chemical Corporation)) can be used.

In addition, a plurality of porous materials (nonwoven fabrics and woven fabrics) having different flow resistances may be laminated. In addition, at least two or more of the porous material, the nonwoven fabric, and the woven fabric may be laminated and used.

A thickness of the porous material (nonwoven fabric and woven fabric) is not particularly limited, and may be a thickness at which a speed of outflow and inflow of gas (air) from the first air chamber 101 can be set to a desired state according to the type of the porous material (nonwoven fabric and woven fabric). The thickness of the porous material (nonwoven fabric and woven fabric) is preferably 1 mm to 50 mm, more preferably 3 mm to 30 mm, and still more preferably 5 mm to 20 mm.

In addition, in the example shown in the drawing, the porous material 104 is configured to be disposed on the surface of the perforated plate 102 opposite to the piezoelectric film 10; but the present invention is not limited thereto, and the porous material (nonwoven fabric and woven fabric) may be disposed in the through-holes 102a of the perforated plate 102.

The driver unit 100 having the above-described configuration is incorporated into the headphone 200.

### <Headphone>

The headphone 200 includes a headband (not shown) and a pair of housings disposed at both end portions of the headband, and is connected to an acoustic device (a music player, a smartphone, or the like) (not shown) in a wired or wireless manner.

FIG. 1 is a cross-sectional view conceptually showing a part of the headphone, and the headphone includes a housing 202 which forms an outer shell of the headphone, the driver unit 100 accommodated in the housing 202, an ear pad 204 disposed on a surface side of the driver unit 100 opposite to the housing 202, and an ear pad locking member 206 for locking the ear pad 204 to the housing 202.

The housing 202 has an opening portion on a surface which is on an ear side of a user in a case where the user wears the headphone 200, and the driver unit 100 is disposed in the housing 202 to block at least a part of the opening portion.

A shape of the housing 202 may be the same as a shape of a housing of a known headphone in the related art, such as a substantially bottomed tubular shape, a substantially spherical cap shape, and a shape represented by a part of a substantially ellipsoidal shape.

In the example shown in FIG. 1, the driver unit 100 is disposed with the piezoelectric film 10 side toward the opening portion of the housing 202 and with the porous material 104 side toward the inside (bottom portion) of the housing 202. In other words, the housing 202 is disposed on the concave surface side of the piezoelectric film 10.

As shown in FIG. 1, in the headphone, a second air chamber 201 defined by the perforated plate 102 of the driver unit 100 and the housing 202 is formed. The second air chamber 201 communicates with the first air chamber 101 through the through-holes 102a and the porous material 104. In addition, in the example shown in FIG. 1, the housing 202 has a through-hole 202a on a bottom surface portion, through which the second air chamber 201 communicates with the outside.

In the example shown in FIG. 1, the second air chamber 201 communicates with the outside by the housing 202 having the through-hole 202a on the bottom surface portion, but the present invention is not limited thereto. For example, the housing 202 may have a through-hole on a side surface portion. Alternatively, the second air chamber 201 may communicate with the outside by having a gap between the housing 202 and the driver unit 100. The housing 202 may not have the through-hole 202a. That is, the headphone may be completely sealed.

In addition, in the example shown in FIG. 1, the porous material 104 is filled in a part of the second air chamber 201; but the present invention is not limited thereto, and the porous material 104 may be filled in an entire region of the second air chamber 201. In addition, the porous material 104 may be divided into a plurality of pieces and disposed in the second air chamber 201.

The ear pad 204 is a substantially annular (donut-shaped) member having cushioning properties, which covers the ear of the user in a case where the user wears the headphone 200. The ear pad 204 is disposed on the opening portion side of the housing 202, that is, the driver unit 100 side. In addition, in the example shown in the drawing, the ear pad 204 is locked to the ear pad locking member 206, and the ear pad locking member 206 is fixed by being connected to the housing 202 or the driver unit 100.

The ear pad 204 is not particularly limited, and a known ear pad in the related art can be appropriately used.

Although not shown, the headphone 200 may further include a member of a known headphone in the related art, such as a circuit for driving the driver unit 100 and a cover protecting the driver unit 100.

Next, an action of the headphone 200 including the driver unit 100 according to the embodiment of the present invention having such a configuration will be described.

As described above, the present inventor has studied adopting, in the driver unit of the headphone, the piezoelectric film having the piezoelectric layer consisting of the polymer-based piezoelectric composite material in which the piezoelectric particles are dispersed in the matrix consisting of the polymer material, and the electrode layers provided on both surfaces of the piezoelectric layer. In a case of being used as the driver unit of the headphone, it is necessary to be small and light and to generate high-quality sound in a wide band in order to be mounted on the headphone. Therefore, the present inventor has considered that it is appropriate to use the piezoelectric film itself as a vibration plate, and to use a piezoelectric film having a protrusion (curved portion) which is formed in a convex shape to protrude to one main surface side, as a configuration in which the piezoelectric film can be made broadband with the piezoelectric film which can be mounted on the headphone.

Here, in the headphone, it is known that a sound pressure in a low-frequency range is improved by bringing an ear and an ear pad into close contact with each other to put an internal air chamber (inside a housing) into a substantially sealed state, that is, by using a so-called sealed type or quasi-sealed type.

However, according to the studies of the present inventor, in a configuration in which a driver unit including a piezoelectric film having a curved portion which is formed in a convex shape to protrude to one main surface side is incorporated into the headphone, in a case where the ear and the ear pad are brought into close contact with each other to put the inside of the housing into a substantially sealed state, resonance or the like occurs due to standing waves inside the housing, and thus a variation (also referred to as a ripple, a peak, or a dip on a frequency characteristic) occurs in the frequency characteristic particularly in the high-frequency range, and a flat frequency characteristic is not obtained, which is a problem.

On the other hand, in the headphone 200 including the driver unit 100 according to the embodiment of the present invention, the perforated plate 102 having the through-holes 102a is provided on the concave surface side of the curved portion 10a of the piezoelectric film 10 of the driver unit 100, and further preferably an acoustic absorption layer consisting of a porous material is provided on the back surface side thereof, whereby the resonance in the housing 202 can be suppressed, and the variation (ripple, peak, or dip on a frequency characteristic) in the frequency characteristic in the high-frequency range can be suppressed to obtain a flat frequency characteristic.

In addition, in the configuration in which the driver unit including the piezoelectric film having the curved portion which is formed in a convex shape to protrude to one main surface side is incorporated into the headphone, it has been found that the curved portion of the piezoelectric film may be deformed (hereinafter, also referred to as abnormal deformation) from the formed shape, which may cause a problem that the sound quality is deteriorated. Specifically, as shown in FIG. 19, in a headphone 1000 in the related art, in a case where the ear pad 204 is pressed against an ear U of a user in a case of being worn on the ear (in FIG. 19, arrow X), the ear pad 204 is deformed, and an appropriate air tightness is ensured in an air chamber surrounded by the ear U, the ear pad 204, and the driver unit (piezoelectric film 10). In this case, since a volume of the air chamber is reduced, an air pressure in the air chamber on the ear side is increased. In this case, a pressure difference occurs between the air chamber on the ear side (convex surface side) of the piezoelectric film 10 and the air chamber on the housing side (concave surface side), but in a case of a soft piezoelectric film, the formed curved portion may be abnormally deformed even with a relatively small pressure difference. It has been found that, in a case where the curved portion is abnormally deformed, as shown in a comparison between a solid line and a broken line in the graph of FIG. 16, the frequency characteristic is changed, which causes the sound quality to deteriorate. In particular, it has been found that the sound pressure is reduced in the low-frequency range.

In addition, in a case of removing the headphone, the curved portion may be abnormally deformed due to a difference in fluctuation of the air pressure between the surface side of the piezoelectric film 10 on the ear pad side and the surface side (housing 202 side) opposite to the surface side.

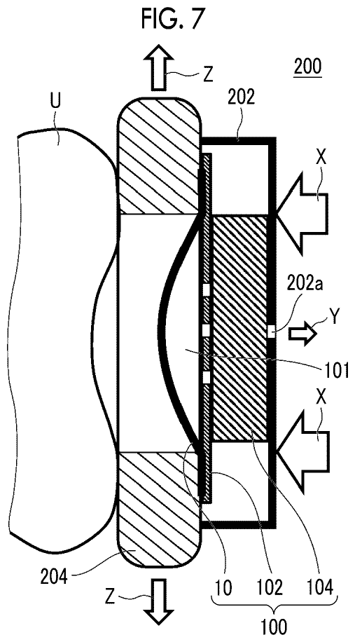

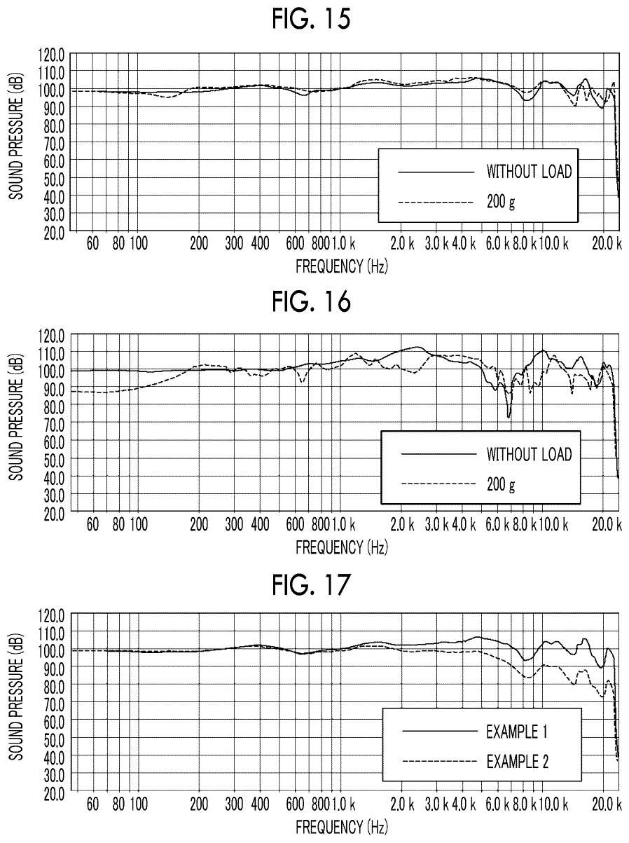

On the other hand, in the headphone 200 including the driver unit 100 according to the embodiment of the present invention, as shown in FIG. 7, in a case where the ear pad 204 is pressed against the ear U of the user in a case of wearing the headphone 200 (in FIG. 7, arrow X), the ear pad 204 is deformed, and an appropriate air tightness is ensured in an air chamber surrounded by the ear U, the ear pad 204, and the driver unit 100 (piezoelectric film 10). Since a volume of the air chamber is reduced, an air pressure in the air chamber is increased. In this case, the first air chamber 101 on the concave surface side of the piezoelectric film 10 is partitioned from the second air chamber by the perforated plate 102, and the back surface side of the perforated plate 102 is preferably covered with the porous material 104, so that the air in the first air chamber 101 can be prevented from instantly leaking to the second air chamber (in FIG. 7, arrow Y). As a result, the piezoelectric film 10 can be suppressed from being deformed by being pushed down by the pressure increase in the air chamber on the ear side. Meanwhile, the air in the air chamber on the ear side surrounded by the ear U, the ear pad 204, and the driver unit 100 (piezoelectric film 10) also leaks through the ear pad 204 (in FIG. 7, arrow Z) or through a gap between the ear pad 204 and the ear U, and thus the air pressure in the air chamber gradually decreases. As a result, the pressure balance is maintained between the convex surface side of the piezoelectric film 10 on the ear pad 204 side and the concave surface side (housing 202 side) opposite to the convex surface side, and thus the curved portion 10a can be prevented from being abnormally deformed. Therefore, as shown by a solid line and a broken line in the graph of FIG. 15, the frequency characteristic is changed, and the sound quality deterioration can also be prevented. As shown in FIG. 15, a flat frequency characteristic can be achieved from the low-frequency range to the high-frequency range. In FIG. 7, for convenience of description, the holding member 106, the holding member 108, and the fastening member 110 are not shown.

In addition, in a case of removing the headphone 200, the difference in fluctuation of the air pressure between the surface side of the piezoelectric film 10 on the ear pad 204 side and the surface side (housing 202 side) opposite to the surface side can be prevented, and the curved portion 10a can be prevented from being deformed.

As described above, in the headphone 200 including the driver unit 100 according to the embodiment of the present invention, the perforated plate 102 having the through-holes 102a and the porous material 104 are disposed on the concave surface side of the piezoelectric film 10 on which the curved portion 10a is formed, and the fluctuation in pressure in the first air chamber 101 on the concave surface side in a case of wearing or removing the headphone 200 is made slow, so that the curved portion 10a can be prevented from being abnormally deformed.

Furthermore, as a preferred aspect, the driver unit 100 according to the embodiment of the present invention includes an acoustic absorption layer consisting of the porous material 104 on the back surface side (side opposite to the piezoelectric film 10) of the perforated plate 102. In the headphone 200 including the driver unit 100, the configuration in which the perforated plate 102 and the acoustic absorption layer consisting of the porous material 104 on the back surface side are provided on the concave surface side (back surface side) of the piezoelectric film 10 is a so-called composite sound-absorbing structure, and a wide range of acoustic absorption characteristics in which features of porous type acoustic absorption, plate vibration type acoustic absorption, and resonance type acoustic absorption can be optionally selected can be realized by selecting an opening ratio of the perforated plate 102, a thickness and a material of the acoustic absorption layer on the back surface side, and the like. Therefore, the occurrence of the standing waves in the housing can be suppressed, and the ripple and the peak or dip on the frequency characteristic can be improved to obtain a flat frequency characteristic.

Here, in the example shown in FIG. 1, the driver unit 100 is configured to be disposed with the piezoelectric film 10 side toward the opening portion of the housing 202 and with the porous material 104 side toward the inside (bottom portion) of the housing 202, and the housing 202 is disposed on the concave surface side of the piezoelectric film 10; but the present invention is not limited thereto. As in a headphone 200b shown in FIG. 8, the driver unit 100 may be configured to be disposed with the piezoelectric film 10 side toward the inside of the housing 202 and with the porous material 104 side toward the opening portion of the housing 202. In other words, the housing 202 may be configured to be disposed on the convex surface side of the piezoelectric film 10.

Even in a case of the configuration of the headphone 200b shown in FIG. 8, the resonance due to the standing waves in the housing 202 can be suppressed, and the variation in the frequency characteristic in the high-frequency range can be suppressed to obtain a flat frequency characteristic.

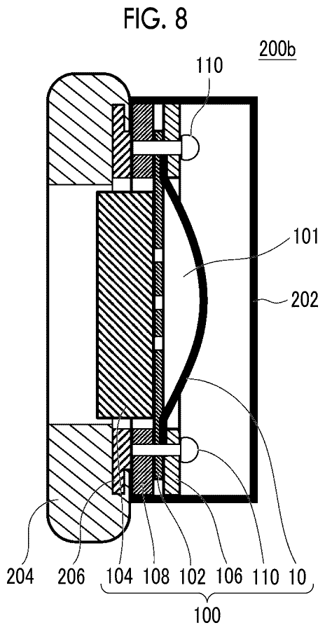

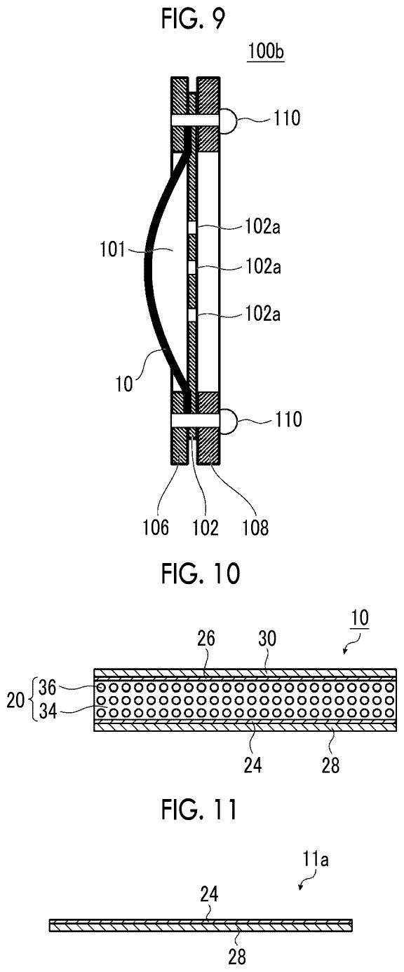

In addition, in the example shown in FIG. 1, the driver unit 100 is configured to include the porous material 104 which is disposed to cover the through-holes 102a of the perforated plate 102; but the present invention is not limited thereto, and the driver unit may be configured not to include the porous material 104 as in a driver unit 100b shown in FIG. 9. The driver unit 100b shown in FIG. 9 has the same configuration as the driver unit 100 shown in FIG. 1, except that the driver unit 100b does not include the porous material 104.

As described above, the combination of the perforated plate 102 and the porous material 104 is a so-called composite sound-absorbing structure, and a wide range of acoustic absorption characteristics in which features of porous-type acoustic absorption, plate vibration-type acoustic absorption, and resonance-type acoustic absorption can be optionally selected can be achieved by selecting an opening ratio of the perforated plate 102, a thickness and a material of the acoustic absorption layer on the back surface side, and the like. Therefore, the occurrence of the standing waves in the housing can be suppressed, and the ripple, the peak or dip, and the like on the frequency characteristic can be improved to obtain a flat frequency characteristic. On the other hand, since the perforated plate 102 alone can realize the acoustic absorption characteristics having the features of the plate vibration-type and the resonance-type, there is a certain effect in suppressing the occurrence of the standing waves in the housing.

From the viewpoint of improving the ripple, the peak or dip, and the like on the frequency characteristic in a high-frequency region to obtain a flat frequency characteristic, a proportion of the total area of the through-holes 102a to an area of a vibration region of the piezoelectric film 10, that is, an area of the curved portion 10a in a plan view is preferably 3% to 70%, more preferably 25% to 65%, and still more preferably 40% to 60%.

In addition, from the viewpoint of improving the ripple, the peak or dip, and the like on the frequency characteristic in the high-frequency region to obtain a flat frequency characteristic, a diameter (circle-equivalent diameter) of each through-hole 102a of the perforated plate 102 is preferably 0.01 mm to 10 mm, more preferably 0.1 mm to 6 mm, and still more preferably 0.5 mm to 4 mm.

Even in the driver unit 100b which does not include the porous material 104, the ripple, the peak or dip, and the like on the frequency characteristic can be improved to obtain a flat frequency characteristic by appropriately setting the total area, the diameter, and the like of the through-holes 102a of the perforated plate 102.

### <Piezoelectric Film>

Next, a layer configuration of the piezoelectric film 10 will be described.

The piezoelectric film 10 includes the piezoelectric layer consisting of the polymer-based piezoelectric composite material containing the piezoelectric particles in the matrix containing the polymer material, and the electrode layers provided on both surfaces of the piezoelectric layer. In a case where a voltage is applied to the electrode layers (electrode pair) which sandwich the piezoelectric layer, the piezoelectric layer stretches and contracts according to the applied voltage. As a result, the piezoelectric film 10 (piezoelectric layer 20) contracts in the thickness direction. At the same time, the piezoelectric film 10 stretches and contracts in the plane direction due to the Poisson's ratio. In this manner, the piezoelectric film 10 can exhibit piezoelectric characteristics.

FIG. 10 is an enlarged view of a part of the piezoelectric film 10.

The piezoelectric film 10 shown in FIG. 10 includes a piezoelectric layer 20 which is a sheet-like material having piezoelectric characteristics, a first electrode layer 24 laminated on one surface of the piezoelectric layer 20, a first protective layer 28 laminated on a surface of the first electrode layer 24 opposite to the piezoelectric layer 20, a second electrode layer 26 laminated on the other surface of the piezoelectric layer 20, and a second protective layer 30 laminated on a surface of the second electrode layer 26 opposite to the piezoelectric layer 20. That is, the piezoelectric film 10 has a configuration in which the piezoelectric layer 20 is sandwiched between the electrode layers and the protective layer is laminated on a surface of the electrode layer, which is not in contact with the piezoelectric layer.

In the present invention, the piezoelectric layer 20 is a polymer-based piezoelectric composite material containing piezoelectric particles 36 in a matrix 34 containing a polymer material, as conceptually shown in FIG. 10.

As a material of the matrix 34 (serving as a matrix and a binder) of the polymer-based piezoelectric composite material constituting the piezoelectric layer 20, it is preferable to use a polymer material having viscoelasticity at normal temperature. In the present specification, the “normal temperature” indicates a temperature range of approximately 0° C. to 50° C.

Here, it is preferable that the polymer-based piezoelectric composite material (piezoelectric layer 20) satisfies the following requirements.

### (i) Flexibility

For example, in a case of being gripped in a state of being loosely bent with a sense of document such as a newspaper and a magazine as a portable device, the polymer-based piezoelectric composite material is continuously subjected to large bending deformation from the outside at a comparatively slow vibration of less than or equal to a few Hz. At this time, in a case where the polymer-based piezoelectric composite material is rigid, large bending stress is generated to that extent, and a crack is generated at an interface between the polymer matrix and the piezoelectric particles, which may lead to breakage. Accordingly, the polymer-based piezoelectric composite material is required to have suitable flexibility. In addition, in a case where strain energy is diffused into the outside as heat, the stress can be relaxed. Therefore, the polymer-based piezoelectric composite material is required to have a suitably large loss tangent.

### (ii) Acoustic Quality

In a speaker, the piezoelectric particles vibrate at a frequency of an audio band of 20 Hz to 20 kHz, and vibration energy causes the entire polymer-based piezoelectric composite material (piezoelectric film) to vibrate integrally so that sound is reproduced. Therefore, in order to increase transmission efficiency of the vibration energy, the polymer-based piezoelectric composite material is required to have appropriate rigidity. In addition, in a case where frequency characteristics of the speaker are smooth, an amount of a change in acoustic quality decreases in a case where the lowest resonance frequency is changed in association with a change in curvature of the speaker. Therefore, the polymer-based piezoelectric composite material is required to have a suitably large loss tangent.

Accordingly, the polymer-based piezoelectric composite material is required to exhibit a behavior of being rigid with respect to a vibration of 20 Hz to 20 kHz and being flexible with respect to a vibration of less than or equal to a few Hz. In addition, the loss tangent of the polymer-based piezoelectric composite material is required to be suitably large with respect to the vibration of all frequencies of 20 kHz or less.

In general, a polymer solid has a viscoelasticity relaxing mechanism, and a molecular movement with a large scale is observed as a decrease (relief) in a storage elastic modulus (Young's modulus) or a maximal value (absorption) in a loss elastic modulus along with an increase in temperature or a decrease in frequency. Among these, the relaxation due to a microbrown movement of a molecular chain in an amorphous region is referred to as main dispersion, and an extremely large relaxing phenomenon is observed. A temperature at which this main dispersion occurs is a glass transition point (Tg), and the viscoelasticity relaxing mechanism is most remarkably observed.

In the polymer-based piezoelectric composite material (piezoelectric layer 20), the polymer-based piezoelectric composite material exhibiting a behavior of being rigid with respect to the vibration of 20 Hz to 20 kHz and being flexible with respect to the slow vibration of less than or equal to a few Hz is achieved by using, as a matrix, a polymer material having a glass transition point at normal temperature, that is, a polymer material having viscoelasticity at normal temperature. In particular, from the viewpoint that such a behavior is suitably exhibited, it is preferable that a polymer material in which the glass transition point at a frequency of 1 Hz is at normal temperature, that is, in a range of 0° C. to 50° C. is used for a matrix of the polymer-based piezoelectric composite material.

As the polymer material having a viscoelasticity at normal temperature, various known materials can be used. It is preferable that a polymer material in which the maximal value of a loss tangent Tan δ at a frequency of 1 Hz according to a dynamic viscoelasticity test at normal temperature, that is, in a range of 0° C. to 50° C. is 0.5 or more is used as the polymer material.

In this manner, in a case where the polymer-based piezoelectric composite material is slowly bent due to an external force, stress concentration on the interface between the polymer matrix and the piezoelectric particles at the maximum bending moment portion is relaxed, and thus high flexibility can be expected.

In the polymer material having a viscoelasticity at normal temperature, it is preferable that a storage elastic modulus (E′) at a frequency of 1 Hz according to the dynamic viscoelasticity measurement is 100 MPa or more at 0° C. and 10 MPa or less at 50° C.

In this manner, a bending moment generated in a case where the polymer-based piezoelectric composite material is slowly bent due to the external force can be reduced, and at the same time, the polymer-based piezoelectric composite material can exhibit a behavior of being rigid with respect to an acoustic vibration of 20 Hz to 20 KHz.

In addition, it is more suitable that a relative permittivity of the polymer material having a viscoelasticity at normal temperature is 10 or more at 25° C. Accordingly, in a case where a voltage is applied to the polymer-based piezoelectric composite material, a higher electric field is applied to the piezoelectric particles in the matrix, and thus a large deformation amount can be expected.

However, in consideration of ensuring favorable moisture resistance and the like, it is suitable that the relative permittivity of the polymer material is 10 or less at 25° C.

Examples of the polymer material having a viscoelasticity at normal temperature and satisfying such conditions include cyanoethylated polyvinyl alcohol (cyanoethylated PVA), polyvinyl acetate, poly(vinylidene chloride-co-acrylonitrile), a polystyrene-vinyl polyisoprene block copolymer, polyvinyl methyl ketone, and polybutyl methacrylate. In addition, as these polymer materials, a commercially available product such as Hybrar 5127 (manufactured by Kuraray Co., Ltd.) can also be suitably used. Among these, as the polymer material, a material having a cyanoethyl group is preferably used, and cyanoethylated PVA is particularly preferably used.

Among these, as the polymer material having viscoelasticity at normal temperature, it is preferable to use a polymer material having a cyanoethyl group and particularly preferable to use cyanoethylated PVA. That is, in the present invention, as the matrix 34 of the piezoelectric layer 20, it is preferable to use a polymer material containing a cyanoethyl group and particularly preferable to use cyanoethylated PVA.

In the following description, the above-described polymer materials typified by cyanoethylated PVA will also be collectively referred to as “polymer material having viscoelasticity at normal temperature”.

These polymer materials having viscoelasticity at normal temperature may be used alone or in combination (mixture) of two or more kinds thereof.

The matrix 34 using such a polymer material having a viscoelasticity at normal temperature may use a plurality of polymer materials in combination as necessary.

That is, in order to control dielectric properties, mechanical properties, or the like, other dielectric polymer materials may be added to the matrix 34 as necessary, in addition to the viscoelastic material such as cyanoethylated PVA.

Examples of the dielectric polymer material which can be added thereto include fluorine-based polymers such as polyvinylidene fluoride, a vinylidene fluoride-tetrafluoroethylene copolymer, a vinylidene fluoride-trifluoroethylene copolymer, a polyvinylidene fluoride-trifluoroethylene copolymer, and a polyvinylidene fluoride-tetrafluoroethylene copolymer; polymers having a cyano group or a cyanoethyl group, such as a vinylidene cyanide-vinyl acetate copolymer, cyanoethyl cellulose, cyanoethyl hydroxysaccharose, cyanoethyl hydroxycellulose, cyanoethyl hydroxypullulan, cyanoethyl methacrylate, cyanoethyl acrylate, cyanoethyl hydroxyethyl cellulose, cyanoethyl amylose, cyanoethyl hydroxypropyl cellulose, cyanoethyl dihydroxypropyl cellulose, cyanoethyl hydroxypropyl amylose, cyanoethyl polyacrylamide, cyanoethyl polyacrylate, cyanoethyl pullulan, cyanoethyl polyhydroxymethylene, cyanoethyl glycidol pullulan, cyanoethyl saccharose, and cyanoethyl sorbitol; and synthetic rubber such as nitrile rubber and chloroprene rubber.

Among these, a polymer material having a cyanoethyl group is suitably used.

In addition, in the matrix 34 of the piezoelectric layer 20, the number of these dielectric polymer materials is not limited to one, and a plurality of kinds of dielectric polymer materials may be added.

In addition, for the purpose of controlling the glass transition point Tg, a thermoplastic resin such as a vinyl chloride resin, polyethylene, polystyrene, a methacrylic resin, polybutene, and isobutylene, and a thermosetting resin such as a phenol resin, a urea resin, a melamine resin, an alkyd resin, and mica may be added to the matrix 34 in addition to the dielectric polymer material.

Furthermore, for the purpose of improving pressure sensitive adhesiveness, a viscosity imparting agent such as rosin ester, rosin, terpene, terpene phenol, and a petroleum resin may be added.

In the matrix 34 of the piezoelectric layer 20, an addition amount of materials to be added, other than the polymer material having viscoelasticity, such as cyanoethylated PVA, is not particularly limited, but is preferably set to 30% by mass or less in terms of the proportion of the materials in the matrix 34.

In this manner, characteristics of the polymer material to be added can be exhibited without impairing the viscoelasticity relaxing mechanism in the matrix 34, so that preferred results such as an increase in permittivity, improvement of heat resistance, and improvement of adhesiveness between the piezoelectric particles 36 and the electrode layer can be obtained.

The piezoelectric layer 20 is a layer consisting of the polymer-based piezoelectric composite material containing the piezoelectric particles 36 in the matrix 34. The piezoelectric particles 36 are dispersed in the matrix 34. It is preferable that the piezoelectric particles 36 are dispersed uniformly (substantially uniform) in the matrix 34.

The piezoelectric particles 36 consist of ceramic particles having a perovskite type or wurtzite type crystal structure.

Examples of the ceramic particles constituting the piezoelectric particles 36 include lead zirconate titanate (PZT), lead lanthanum zirconate titanate (PLZT), barium titanate (BaTiO₃), zinc oxide (ZnO), and a solid solution (BFBT) of barium titanate and bismuth ferrite (BiFeO₃).

A particle diameter of the piezoelectric particles 36 is not limited, and may be suitably selected depending on the size, the applications, and the like of the piezoelectric film 10. The particle diameter of the piezoelectric particles 36 is preferably 1 to 10 μm.

By setting the particle diameter of the piezoelectric particles 36 to be within the above-described range, preferred results in terms of achieving both excellent piezoelectric characteristics and flexibility of the piezoelectric film 10 can be obtained.

The piezoelectric particles 36 in the piezoelectric layer 20 may be uniformly and regularly dispersed in the matrix 34, or may be uniformly dispersed in the matrix 34 even in a case where the piezoelectric particles 36 are irregularly dispersed in the matrix 34.

In the piezoelectric film 10, a ratio between an amount of the matrix 34 and an amount of the piezoelectric particles 36 in the piezoelectric layer 20 is not limited, and may be appropriately set according to the size and the thickness of the piezoelectric film 10 in the plane direction, the applications, the required characteristics, and the like.

A volume fraction of the piezoelectric particles 36 in the piezoelectric layer 20 is preferably 30% to 80%, more preferably 50% or more, and still more preferably 50% to 80%.

By setting the ratio between the amount of the matrix 34 and the amount of the piezoelectric particles 36 to be within the above-described range, preferred results in terms of achieving both of excellent piezoelectric characteristics and flexibility can be obtained.

A thickness of the piezoelectric layer 20 in the piezoelectric film 10 is not particularly limited, and may be appropriately set according to the characteristics required for the piezoelectric film 10, and the like.

It is advantageous that the thickness of the piezoelectric layer 20 increases large in terms of stiffness such as the strength of stiffness of a so-called sheet-like material, but the voltage (potential difference) required to stretch and contract the piezoelectric film 10 increases by the same amount.

The thickness of the piezoelectric layer 20 is preferably 10 to 300 μm, more preferably 20 to 200 μm, and still more preferably 30 to 150 μm.

By setting the thickness of the piezoelectric layer 20 to be within the above-described ranges, preferred results in terms of achieving both ensuring of the stiffness and moderate elasticity can be obtained.

In addition, it is preferable that the piezoelectric layer 20 is subjected to a polarization treatment (poling) in the thickness direction. In a case where a voltage is applied to the electrode layers (electrode pair) which sandwich the piezoelectric layer 20, the piezoelectric particles 36 in the piezoelectric layer 20 stretch and contract in the polarization direction according to the applied voltage. As a result, the piezoelectric film 10 (piezoelectric layer 20) contracts in the thickness direction. At the same time, the piezoelectric film 10 stretches and contracts in the plane direction due to the Poisson's ratio. In this manner, the piezoelectric film 10 can exhibit piezoelectric characteristics.

As shown in FIG. 10, the piezoelectric film 10 has a configuration in which the first electrode layer 24 is provided on one surface of the piezoelectric layer 20, the first protective layer 28 is provided thereon, the second electrode layer 26 is provided on the other surface of the piezoelectric layer 20, and the second protective layer 30 is provided thereon. Here, the first electrode layer 24 and the second electrode layer 26 form an electrode pair.

That is, the piezoelectric film 10 has a configuration in which both surfaces of the piezoelectric layer 20 are sandwiched between the electrode pair, that is, the first electrode layer 24 and the second electrode layer 26, and this laminate is sandwiched between the first protective layer 28 and the second protective layer 30.

In this way, in the piezoelectric film 10, a region sandwiched between the first electrode layer 24 and the second electrode layer 26 stretches and contracts according to an applied voltage.

The terms “first” and “second” in the electrode layers and the protective layers are added for convenience in describing the piezoelectric film 10. Therefore, the terms “first” and “second” in the present invention have no technical meanings and are irrelevant to the actual usage state.

The piezoelectric film 10 in the present invention may include, in addition to those layers, for example, a bonding layer for bonding the electrode layer and the piezoelectric layer 20 to each other, and a bonding layer for bonding the electrode layer and the protective layer to each other.

The bonding agent may be an adhesive or a pressure sensitive adhesive. In addition, the same material as the polymer material obtained by removing the piezoelectric particles 36 from the piezoelectric layer 20, that is, the matrix 34 can also be suitably used as the bonding agent. The bonding layer may be provided on both the first electrode layer 24 side and the second electrode layer 26 side, or may be provided only on one of the first electrode layer 24 side or the second electrode layer 26 side.

The first protective layer 28 and the second protective layer 30 in the piezoelectric film 10 have a function of coating the first electrode layer 24 and the second electrode layer 26 and imparting moderate stiffness and mechanical strength to the piezoelectric layer 20. That is, the piezoelectric layer 20 consisting of the matrix 34 and the piezoelectric particles 36 in the piezoelectric film 10 exhibits extremely excellent flexibility under bending deformation at a slow vibration, but may have insufficient stiffness or mechanical strength depending on the applications. As a compensation for this, the piezoelectric film 10 is provided with the first protective layer 28 and the second protective layer 30.

The first protective layer 28 and the second protective layer 30 have the same configuration despite of different disposition positions. Accordingly, in the following description, in a case where it is not necessary to distinguish the first protective layer 28 from the second protective layer 30, both members are collectively referred to as a protective layer.

The protective layer is not limited, and various sheet-like materials can be used as the protective layer, and suitable examples thereof include various resin films.

Among these, from the viewpoint of excellent mechanical characteristics and heat resistance, a resin film consisting of polyethylene terephthalate (PET), polypropylene (PP), polystyrene (PS), polycarbonate (PC), polyphenylene sulfide (PPS), polymethylmethacrylate (PMMA), polyetherimide (PEI), polyimide (PI), polyethylene naphthalate (PEN), triacetyl cellulose (TAC), a cyclic olefin-based resin, and the like is suitably used.

A thickness of the protective layer is not limited. In addition, the thicknesses of the first protective layer 28 and the second protective layer 30 are basically the same as each other, but may be different from each other.

Here, in a case where the stiffness of the protective layer is extremely high, not only is the stretch and contraction of the piezoelectric layer 20 constrained, but also the flexibility is impaired. Therefore, it is advantageous that the thickness of the protective layer decrease except for a case where the mechanical strength or excellent handleability as a sheet-like material is required.

In a case where the thickness of the protective layer in the piezoelectric film 10 is two times or less the thickness of the piezoelectric layer 20, preferred results in terms of achieving both ensuring of the stiffness and moderate elasticity can be obtained.

For example, in a case where the thickness of the piezoelectric layer 20 is 50 μm and the protective layer consists of PET, the thickness of the protective layer is preferably 100 μm or less, more preferably 50 μm or less, and still more preferably 25 μm or less.

In the piezoelectric film 10, the first electrode layer 24 is formed between the piezoelectric layer 20 and the first protective layer 28, and the second electrode layer 26 is formed between the piezoelectric layer 20 and the second protective layer 30. The first electrode layer 24 and the second electrode layer 26 are provided to apply a voltage to the piezoelectric layer 20 (piezoelectric film 10).

The first electrode layer 24 and the second electrode layer 26 are basically the same, except that the positions are different. Accordingly, in the following description, in a case where it is not necessary to distinguish the first electrode layer 24 and the second electrode layer 26, both members are collectively referred to as an electrode layer.

In the present invention, a forming material of the electrode layer is not limited, and various conductors can be used as the forming material. Specific examples thereof include metals such as carbon, palladium, iron, tin, aluminum, nickel, platinum, gold, silver, copper, titanium, chromium, and molybdenum, alloys thereof, laminates and composites of these metals and alloys, and indium tin oxide. Specific examples thereof also include conductive polymers such as polyethylene dioxythiophene-polystyrene sulfonic acid (PEDOT/PPS). Among these, copper, aluminum, gold, silver, platinum, or indium tin oxide is suitably exemplified as the electrode layer. Among these, from the viewpoint of the conductivity, the cost, and the flexibility, copper is more preferable.

In addition, a method of forming the electrode layer is not limited, and various known methods, for example, a vapor-phase deposition method (a vacuum film forming method) such as vacuum vapor deposition or sputtering, a film forming method using plating, and a method of bonding a foil formed of the materials described above can be used.

Among these, particularly from the viewpoint of ensuring the flexibility of the piezoelectric film 10, a thin film made of copper, aluminum, or the like formed by vacuum vapor deposition is suitably used as the electrode layer. Among these, a thin film made of copper, which is formed by vacuum vapor deposition, is particularly suitably used.

A thickness of the electrode layer is not limited. In addition, the thicknesses of the first electrode layer 24 and the second electrode layer 26 are basically the same as each other, but may be different from each other.

Here, similarly to the above-described protective layer, in a case where the stiffness of the electrode layer is extremely high, not only is the stretch and contraction of the piezoelectric layer 20 constrained, but also the flexibility is impaired. Therefore, it is advantageous that the thickness of the electrode layer is reduced in a case where an electrical resistance is not excessively high.

In the piezoelectric film 10, it is suitable that a product of the thickness of the electrode layer and the Young's modulus thereof is less than a product of the thickness of the protective layer and the Young's modulus thereof because the flexibility is not considerably impaired.

For example, in a case of a combination consisting of the protective layer formed of PET (Young's modulus: approximately 6.2 GPa) and the electrode layer formed of copper (Young's modulus: approximately 130 GPa), assuming that the thickness of the protective layer is 25 μm, the thickness of the electrode layer is preferably 1.2 μm or less, more preferably 0.3 μm or less, and still more preferably 0.1 μm or less.

As described above, the piezoelectric film 10 has a configuration in which the piezoelectric layer 20 obtained by dispersing the piezoelectric particles 36 in the matrix 34 containing the polymer material is sandwiched between the first electrode layer 24 and the second electrode layer 26, and this laminate is sandwiched between the first protective layer 28 and the second protective layer 30.

In such a piezoelectric film 10, it is preferable that the maximal value of the loss tangent (Tan δ) at a frequency of 1 Hz according to the dynamic viscoelasticity measurement is present at normal temperature, and it is more preferable that the maximal value at which the loss tangent is 0.1 or more is present at normal temperature.

In this manner, even in a case where the piezoelectric film 10 is subjected to large bending deformation at a relatively slow vibration of less than or equal to a few Hz from the outside, since the strain energy can be effectively diffused to the outside as heat, occurrence of cracks at the interface between the polymer matrix and the piezoelectric particles can be prevented.

In the piezoelectric film 10, it is preferable that the storage elastic modulus (E′) at a frequency of 1 Hz according to the dynamic viscoelasticity measurement is 10 to 30 GPa at 0° C. and 1 to 10 GPa at 50° C. The same applies to the conditions for the piezoelectric layer 20.

In such a manner, the piezoelectric film 10 may have large frequency dispersion in the storage elastic modulus (E′) at normal temperature. That is, the piezoelectric film 10 can exhibit a behavior of being rigid with respect to the vibration of 20 Hz to 20 kHz and being flexible with respect to the vibration of less than or equal to a few Hz.

In addition, in the piezoelectric film 10, it is preferable that a product of the thickness and the storage elastic modulus (E′) at a frequency of 1 Hz according to the dynamic viscoelasticity measurement is 1.0×10⁵ to 2.0×10⁶ N/m at 0° C. and 1.0×10⁵ to 1.0×10⁶ N/m at 50° C. The same applies to the conditions for the piezoelectric layer 20.

In this manner, the piezoelectric film 10 may have moderate stiffness and mechanical strength within a range not impairing the flexibility and the acoustic characteristics.

Furthermore, in the piezoelectric film 10, it is preferable that the loss tangent (Tan δ) at a frequency of 1 kHz at 25° C. is 0.05 or more in a master curve obtained from the dynamic viscoelasticity measurement. The same applies to the conditions for the piezoelectric layer 20.

In this manner, the frequency characteristics of the speaker including the piezoelectric film 10 are smooth, so that an amount of change in acoustic quality in a case where the lowest resonance frequency f₀ is changed according to a change in curvature of the speaker can be decreased.

In addition, in the present invention, the storage elastic modulus (Young's modulus) and the loss tangent of the piezoelectric film 10, the piezoelectric layer 20, and the like may be measured by a known method. As an example, the measurement may be performed using a dynamic viscoelasticity measuring device DMS6100 (manufactured by SII Nanotechnology Inc.).

Examples of measurement conditions include conditions with a measurement frequency of 0.1 Hz to 20 Hz (0.1 Hz, 0.2 Hz, 0.5 Hz, 1 Hz, 2 Hz, 5 Hz, 10 Hz, and 20 Hz), a measurement temperature of −50° C. to 150° C., a temperature rising rate of 2° C./min (in a nitrogen atmosphere), a sample size of 40 mm×10 mm (including the clamped region), and a chuck-to-chuck distance of 20 mm.

In the driver unit 100, an external power supply (signal source) which applies a driving voltage, that is, which supplies a driving power (driving signal) for expanding and contracting the piezoelectric film 10 is connected to the first electrode layer 24 and the second electrode layer 26 of the piezoelectric film 10.

The external power supply (signal source) is not limited, and may be a direct current power supply or an alternating current power supply. In addition, as the driving voltage, a driving voltage capable of suitably driving the piezoelectric films 10 may be suitably set in accordance with the thickness, forming material, and the like of the piezoelectric layer 20 in the piezoelectric film 10.

A method of leading out electrodes from the first electrode layer 24 and the second electrode layer 26 is not limited, and various known methods can be used.

Examples thereof include a method of connecting a conductor such as a copper foil to the first electrode layer 24 and the second electrode layer 26 and leading-out the electrodes to the outside, and a method of forming through-holes in the first protective layer 28 and the second protective layer 30 with a laser or the like, filling the through-holes with a conductive material, and leading-out the electrodes to the outside.

Examples of a suitable method of leading out the electrodes include the method described in JP2014-209724A and the method described in JP2016-015354A.

As described above, the piezoelectric film 10 includes the piezoelectric layer 20 consisting of the polymer-based piezoelectric composite material containing the piezoelectric particles 36 in the matrix 34 containing the polymer material, and the electrode layers (the first electrode layer 24 and the second electrode layer 26) provided on both surfaces of the piezoelectric layer 20. In addition, the piezoelectric film 10 includes the protective layers (the first protective layer 28 and the second protective layer 30) provided on the respective electrode layers.

In a case where a voltage is applied to the first electrode layer 24 and the second electrode layer 26 of the piezoelectric film 10 including such a piezoelectric layer 20, the piezoelectric particles 36 stretch and contract in the polarization direction according to the applied voltage. As a result, the piezoelectric film 10 (piezoelectric layer 20) contracts in the thickness direction. At the same time, the piezoelectric film 10 stretches and contracts in the in-plane direction due to the Poisson's ratio. A degree of stretch and contraction is approximately 0.01% to 0.1%.

As described above, the thickness of the piezoelectric layer 20 is preferably approximately 10 to 300 μm. Accordingly, the degree of stretch and contraction in the thickness direction is as extremely small as approximately 0.3 μm at the maximum.

On the contrary, the piezoelectric film 10, that is, the piezoelectric layer 20, has a size much larger than the thickness in a plane direction. Therefore, for example, in a case where the diameter of the curved portion 10a of the piezoelectric film 10 is 10 cm, by the application of the voltage, the piezoelectric film 10 (curved portion 10a) expands and contracts in the plane direction by at most approximately 0.1 mm.

The piezoelectric film 10 generates sound by the vibration in the thickness direction. That is, the driver unit 100 vibrates according to the magnitude of the voltage (driving voltage) applied to the piezoelectric film 10, and generates a sound according to the driving voltage applied to the piezoelectric film 10.

### <Method for Manufacturing Piezoelectric Film>

Next, an example of a manufacturing method of the piezoelectric film 10 will be described with reference to FIGS. 11 to 13.

First, as shown in FIG. 11, a sheet-like material 11a in which the first electrode layer 24 has been formed on a surface of the first protective layer 28 is prepared. Furthermore, as conceptually shown in FIG. 13, a sheet-like material 11c in which the second electrode layer 26 has been formed on a surface of the second protective layer 30 is prepared.

The sheet-like material 11a may be produced by forming a copper thin film or the like as the first electrode layer 24 on the surface of the first protective layer 28 using vacuum vapor deposition, sputtering, plating, or the like. Similarly, the sheet-like material 11c may be produced by forming a copper thin film or the like as the second electrode layer 26 on the surface of the second protective layer 30 using vacuum vapor deposition, sputtering, plating, or the like.

Alternatively, a sheet-like material of a commercially available product in which a copper thin film or the like is formed on a protective layer may be used as the sheet-like material 11a and/or the sheet-like material 11c.

The sheet-like material 11a and the sheet-like material 11c may be of the same type or different types.

In a case where the protective layer is extremely thin and thus the handleability is degraded, the protective layer with a separator (temporary support) may be used as necessary. PET having a thickness of 25 to 100 μm, or the like can be used as the separator. The separator may be removed after thermal compression bonding of the electrode layer and the protective layer.

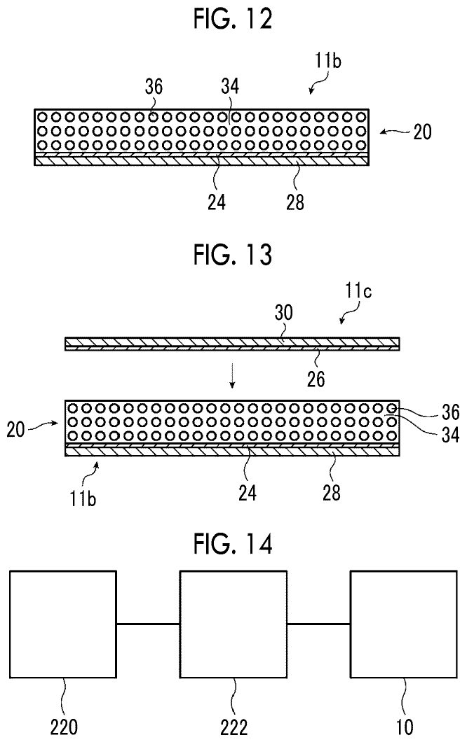

Next, as shown in FIG. 12, the first electrode layer 24 of the sheet-like material 11a is coated with a coating material (coating composition) forming the piezoelectric layer 20, and the coating material is cured to form the piezoelectric layer 20. In this manner, a piezoelectric laminate 11b in which the sheet-like material 11a and the piezoelectric layer 20 are laminated is produced.

The piezoelectric layer 20 can be formed by various methods depending on the forming material of the piezoelectric layer 20.

As an example, first, the coating material is prepared by dissolving the above-described polymer material such as cyanoethylated PVA in an organic solvent, adding the piezoelectric particles 36 such as PZT particles thereto, and stirring the solution.

The organic solvent is not limited, and various organic solvents such as dimethylformamide (DMF), methyl ethyl ketone (MEK), and cyclohexanone can be used. In a case where the sheet-like material 11a is prepared and the coating material is prepared, the coating material is cast (applied) onto the sheet-like material 11a, and the organic solvent is evaporated and dried. In this manner, as shown in FIG. 12, the piezoelectric laminate 11b in which the first electrode layer 24 is provided on the first protective layer 28 and the piezoelectric layer 20 is laminated on the first electrode layer 24 is produced.

A casting method of the coating material is not limited, and all known methods (coating devices) such as a bar coater, a slide coater, and a doctor knife can be used.

Alternatively, in a case where the polymer material is a material that can be heated and melted, the piezoelectric laminate 11b as shown in FIG. 12 may be produced by heating and melting the polymer material to produce a melt obtained by adding the piezoelectric particles 36 to the melted material, extruding the melt on the sheet-like material 11a as shown in FIG. 11 in a sheet shape by carrying out extrusion molding or the like, and cooling the laminate.

As described above, in the piezoelectric layer 20 a polymer piezoelectric material such as PVDF may be added to the matrix 34, in addition to the polymer material having viscoelasticity at normal temperature.

In a case where the polymer piezoelectric material is added to the matrix 34, the polymer piezoelectric material to be added to the above-described coating material may be dissolved. Alternatively, the polymer piezoelectric material to be added may be added to the heated and melted polymer material having viscoelasticity at normal temperature so that the polymer piezoelectric material is heated and melted.

After forming the piezoelectric layer 20, a calender treatment may be performed as necessary. The calender treatment may be performed once or a plurality of times.

As is well known, the calender treatment is a treatment in which the surface to be treated is pressed while being heated by a heating press, a heating roller, or the like to flatten the surface.

Next, the piezoelectric layer 20 of the piezoelectric laminate 11b is subjected to a polarization treatment (poling). The polarization treatment of the piezoelectric layer 20 may be performed before the calender treatment, but it is preferable that the polarization treatment is performed after the calender treatment.

A method of performing the polarization treatment on the piezoelectric layer 20 is not limited, and a known method can be used. For example, electric field poling in which DC electric field is directly applied to a target to be subjected to the polarization treatment, a corona poling treatment, or the like is exemplified. In a case of performing the electric field poling, the electric field poling treatment may be performed using the first electrode layer 24 and the second electrode layer 26 by forming the second electrode layer 26 before the polarization treatment.

In addition, in the piezoelectric film 10 according to the present invention, the polarization treatment is performed in the thickness direction instead of the plane direction of the piezoelectric layer 20.

Next, as shown in FIG. 13, the sheet-like material 11c which has been prepared in advance is laminated on the piezoelectric layer 20 side of the piezoelectric laminate 11b which has been subjected to the polarization treatment, such that the second electrode layer 26 faces the piezoelectric layer 20.

Furthermore, the piezoelectric film 10 as shown in FIG. 10 is produced by subjecting the laminate to a thermal compression bonding using a heating press device, a heating roller, or the like such that the laminate is sandwiched between the first protective layer 28 and the second protective layer 30, and bonding the piezoelectric laminate 11b to the sheet-like material 11c.

Alternatively, the piezoelectric film 10 may be produced by bonding and preferably further compression-bonding the piezoelectric laminate 11b and the sheet-like material 11c to each other using an adhesive. As the adhesive in this case, the same material as the matrix of the piezoelectric layer 20 can be used.

Next, in the forming step, the produced piezoelectric film 10 is subjected to heating compression forming to form the curved portion 10a having a shape which protrudes to one main surface side and is recessed to the other main surface side.

A method of the heating compression forming is not particularly limited, and various known processing methods of resin films can be used. As an example, the piezoelectric film 10 can be heated and compression-molded using a forming device with a mold having a shape corresponding to the shape of the curved portion 10a to be formed, thereby forming the curved portion 10a having a desired shape.

The piezoelectric film 10 may be produced using the cut sheet-like material 11a and the cut sheet-like material 11c, or may be produced by roll-to-roll.

The produced piezoelectric film may be cut into a desired shape according to various applications.

The piezoelectric film 10 to be produced in the above-described manner is polarized in the thickness direction instead of the plane direction, and thus excellent piezoelectric characteristics are obtained even in a case where a stretching treatment is not performed after the polarization treatment. Therefore, the piezoelectric film 10 has no in-plane anisotropy as a piezoelectric characteristic, and stretches and contracts isotropically in all directions in the plane direction in a case where a driving voltage is applied.

As the piezoelectric film 10 included in the driver unit 100, not only a configuration in which one piezoelectric film 10 in which the piezoelectric layer 20 is sandwiched between the first electrode layer 24 and the second electrode layer 26 and is sandwiched between the first protective layer 28 and the second protective layer 30 (the configuration shown in FIG. 10) is used as described above, but also a configuration in which a plurality of piezoelectric films 10 are laminated may be used. The configuration in which a plurality of piezoelectric films 10 are laminated is preferable in that a shape having the curved portion 10a is stably maintained in a case where the size of the piezoelectric film 10 is increased. In the configuration in which a plurality of piezoelectric films 10 are laminated, the piezoelectric films 10 may be laminated through a bonding layer. As the bonding layer, an adhesive layer is preferable in terms of adhesiveness. Specific examples of a material for forming the bonding layer include thermoplastic polyester-based hot melt material. A thickness of the bonding layer is preferably 5 to 50 μm and more preferably 10 to 30 μm.

In a case where a plurality of piezoelectric films 10 are laminated, first, a plurality of piezoelectric films 10 cut to a predetermined size are prepared, and the piezoelectric films 10 are bonded to each other with a hot melt agent or the like to be laminated. In this case, it is preferable that electrode drawing-out portions of the respective piezoelectric films 10 do not come into contact with each other. For example, in a case of a configuration in which the piezoelectric film 10 is provided with an out-island portion which protrudes in the plane direction for drawing out the electrode, it is preferable to laminate the piezoelectric films 10 such that the out-island portions do not overlap.

Next, the laminate in which the plurality of piezoelectric films 10 are laminated is heated and compression-molded to form the curved portion.

Thereafter, the electrode is drawn out from the electrode layer of each piezoelectric film. For example, in a case of a configuration in which each piezoelectric film has the out-island portion, a through-hole can be formed in the protective layer of the out-island portion by laser processing or the like, and a conductive material can be filled in the through-hole to draw out the electrode to the outside.

The two electrode layers of each piezoelectric film are connected to the external power supply (signal source), and in this case, a wiring is connected thereto such that an appropriate polarity of the alternating current signal is applied in accordance with the polarization direction of each piezoelectric layer so that each piezoelectric film is driven in phase.

### <Suitable Embodiment of Driver Unit>

In the driver unit including the piezoelectric film 10, in a case where the frequency characteristic is such that the sound pressure in the high-frequency range is higher than the sound pressure in the low-frequency range, a series resistor is provided for the input signal, so that the applied voltage to the piezoelectric film 10 in the high-frequency range is reduced, the sound pressure in the high-frequency range is gradually reduced, and thus the frequency characteristic is flattened. As a result, the low-frequency range which is masked by the high sound pressure in the high-frequency range is easily heard.

Specifically, as shown in the block diagram of FIG. 14, a resistor 222 is connected between a signal source 220 and the piezoelectric film 10.

The signal source 220 is various known players which is connected to the headphone. In addition, the resistor 222 is disposed in the headphone (inside the housing), and is connected to a wiring connected to the electrode layers of the piezoelectric film 10.

In the piezoelectric film, a configuration in which the piezoelectric layer as a dielectric is sandwiched between the electrode pair is represented by an equivalent circuit in which a static capacitance, an equivalent series inductance, and an equivalent series resistance are connected in series, as in a capacitor or the like. Here, in an audible range (20 Hz to 20 kHz) where the piezoelectric film is used, the equivalent series inductance does not contribute, and thus the piezoelectric film 10 can be expressed as an equivalent circuit in which a capacitance C and the equivalent series resistance ESR are connected in series.

In such an equivalent circuit, since the capacitive reactance Xc=1/(2π×f×C) due to the capacitance C is inversely proportional to a frequency f of the power source, the capacitive reactance Xc decreases as the frequency increases. The capacitive reactance Xc is a ratio between the voltage and the current in a case where the piezoelectric layer is driven.

For simplicity, in a case where the impedance Z of the piezoelectric film is assumed to be only the capacitive reactance Xc, the impedance Z is assumed to be 8,000Ω at a frequency f of 100 Hz, a resistance of 200Ω is assumed to be connected in series to the piezoelectric film, and an operating voltage of 10 Vrms is applied, a voltage Vrms1 applied to the piezoelectric film is approximately 9.8 V, and a voltage Vrms2 applied to the resistor is approximately 0.2 V as shown in Table 1. Next, in a case where the frequency f is 1,000 Hz, the impedance Z of the piezoelectric film is 800Ω, so that the voltage Vrms1 applied to the piezoelectric film is 8.0 V and the voltage Vrms2 applied to the resistor is 2.0 V. Next, in a case where the frequency f is 10,000 Hz, the impedance Z of the piezoelectric film is 80Ω, so that the voltage Vrms1 applied to the piezoelectric film is approximately 2.9 V and the voltage Vrms2 applied to the resistor is approximately 7.1 V. Furthermore, in a case where the frequency f is 20,000 Hz, the impedance Z of the piezoelectric film is 40 (2, so that the voltage Vrms1 applied to the piezoelectric film is approximately 1.7 V and the voltage Vrms2 applied to the resistor is approximately 8.3 V.

Table 1 also shows a result of calculating the change amount of the sound pressure from the voltage ratio.

TABLE 1

| | Frequency f | Hz | 100 | 1000 | 10000 | 20000 |
|---|---|---|---|---|---|---|
| Piezoelectric film | Impedance Z | Ω | 8000 | 800 | 80 | 40 |
| | Voltage Vrms1 | V | 9.8 | 8.0 | 2.9 | 1.7 |
| Resistance | Resistance value R | Ω | 200 | 200 | 200 | 200 |
| | Voltage Vrms2 | V | 0.2 | 2.0 | 7.1 | 8.3 |

| | | | | | |
|---|---|---|---|---|---|
| Change amount of sound pressure | dB | −0.2 | −1.9 | −10.9 | −15.6 |

As described above, in a case where the resistor is connected in series to the piezoelectric film, the voltage applied to the piezoelectric film is reduced as the frequency of the applied voltage (signal) is increased. Here, since the piezoelectric film is voltage-driven, as the frequency is increased, the voltage applied to the piezoelectric film is reduced, and the sound pressure can be reduced as the high-frequency range is increased as compared with a case in which there is no resistor. Therefore, in the driver unit including the piezoelectric film, in a case where the frequency characteristic is such that the sound pressure in the high-frequency range is higher than the sound pressure in the low-frequency range, the resistor is connected in series to the piezoelectric film, so that the applied voltage to the piezoelectric film in the high-frequency range is reduced, the sound pressure in the high-frequency range is gradually reduced, and the frequency characteristic is flattened.

A value of the resistor connected to the piezoelectric film may be appropriately set according to the area of the piezoelectric film, the frequency characteristic, the driving voltage, the impedance, and the like. In a case where a size of the driver unit (curved portion of the piezoelectric film) is Φ6 cm, the series resistance value is preferably 100 to 1,000Ω, more preferably 200 to 700Ω, and still more preferably 300 to 500Ω.

The configuration in which the resistor is connected in series between the piezoelectric film and the signal source can be combined with the driver unit having the piezoelectric film having the curved portion and the perforated plate laminated on the concave surface side of the curved portion, in which the first air chamber defined by the concave surface of the piezoelectric film and the perforated plate communicates with the outside through the through-holes formed in the perforated plate, to further flatten the frequency characteristic. However, the configuration in which the resistor is connected in series between the piezoelectric film and the signal source is not limited to the combination with the driver unit having the above-described configuration, and can exhibit the effect of flattening the frequency characteristic in a combination with a driver unit (electroacoustic transducer) including a piezoelectric film having a piezoelectric layer consisting of a polymer-based piezoelectric composite material in which piezoelectric particles are contained in a matrix containing a polymer material, and electrode layers provided on both surfaces of the piezoelectric layer.

Here, in the above-described example, the piezoelectric film 10 included in the driver unit is configured to have the first electrode layer 24 and the first protective layer 28 on one surface of the piezoelectric layer 20 and to have the second electrode layer 26 and the second protective layer 30 on the other surface, but the present invention is not limited thereto.

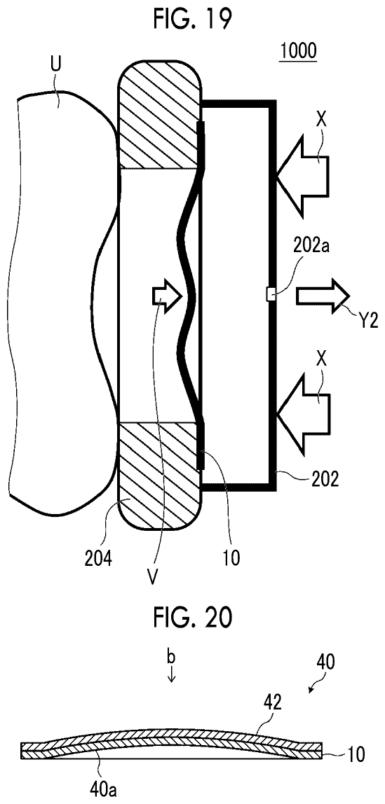

FIG. 20 conceptually shows another example of the piezoelectric film included in the driver unit according to the embodiment of the present invention.

A piezoelectric film 40 shown in FIG. 20 has a configuration in which a reinforcing sheet 42 is laminated on the above-described piezoelectric film 10, and a laminate (piezoelectric film 40) in which the piezoelectric film 10 and the reinforcing sheet 42 are laminated has a curved portion 40a which is formed to protrude to one main surface side and to be recessed to the other main surface side.

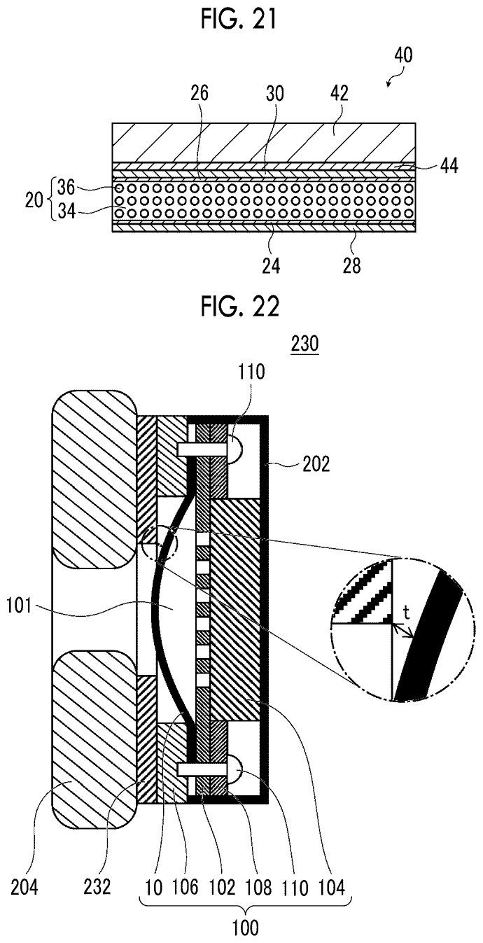

FIG. 21 shows a partially enlarged cross-sectional view of the piezoelectric film 40. The piezoelectric film 40 shown in FIG. 21 includes a piezoelectric layer 20 which is a sheet-like material having piezoelectric characteristics, a first electrode layer 24 laminated on one surface of the piezoelectric layer 20, a first protective layer 28 laminated on a surface of the first electrode layer 24 opposite to the piezoelectric layer 20, a second electrode layer 26 laminated on the other surface of the piezoelectric layer 20, a second protective layer 30 laminated on a surface of the second electrode layer 26 opposite to the piezoelectric layer 20, a reinforcing sheet 42 laminated on a side of the second protective layer 30 opposite to the piezoelectric layer 20 side, and a pressure-sensitive adhesive layer 44 bonding the second protective layer 30 and the reinforcing sheet 42 to each other. The piezoelectric layer 20, the first electrode layer 24, the first protective layer 28, the second electrode layer 26, and the second protective layer 30 have the same configurations as those in the example shown in FIG. 10, and thus the description thereof will not be repeated. In addition, the pressure-sensitive adhesive layer 44 may be a weakly adhesive layer which can be easily peeled off.

The reinforcing sheet 42 is a sheet-like member, and suitable examples thereof include various resin films. Examples of the resin film used for the reinforcing sheet 42 include the same resin films as those used for the protective layer described above. In addition, as the reinforcing sheet 42, a nonwoven fabric, a woven fabric, or the like can also be used. Examples of the nonwoven fabric and the woven fabric used as the reinforcing sheet 42 include the nonwoven fabric and the woven fabric used for the porous material described above. In addition, paper or Japanese paper can also be used as the nonwoven fabric, and cheesecloth can also be used as the woven fabric.

In a case where the piezoelectric film 40 has the reinforcing sheet 42 and integrally forms the curved portion 40a, the abnormal deformation of the curved portion 40a in a case of wearing or removing the headphone in which the driver unit including the piezoelectric film 40 is incorporated can be more suitably suppressed. In addition, in a case where the piezoelectric film 40 has the reinforcing sheet 42, the curved portion 40a is less likely to be abnormally deformed as the piezoelectric film 40 is subjected to an impact due to a fall or the like, or as the user touches the curved portion 40a of the piezoelectric film 40, in addition to the case of wearing the headphone. In addition, handleability during manufacturing is also improved.

In addition, even in a case where the curved portion is abnormally deformed once and the original shape is restored, a deformation mark remains, which may cause a deterioration in the appearance or may affect the acoustic performance, but the piezoelectric film 40 has the reinforcing sheet 42, so that the deformation mark is less likely to remain.

The same effect as that of the reinforcing sheet 42 can be obtained even in the driver unit which does not have the perforated plate.

A thickness of the reinforcing sheet 42 depends on the thickness of the protective layer, the material of the reinforcing sheet 42, and the like, but from the viewpoint of suppressing the abnormal deformation of the curved portion 40a, it is preferably 5 μm or more, more preferably 10 μm or more, and still more preferably 20 μm or more. On the other hand, in a case where the reinforcing sheet 42 is too thick, the vibration of the piezoelectric film 40 may be suppressed, which may cause a decrease in the sound pressure. Therefore, the thickness of the reinforcing sheet 42 is preferably 100 μm or less, more preferably 75 μm or less, and still more preferably 50 μm or less.

Here, in a case where the thickness of the protective layer is sufficiently thick within a range in which the thickness does not affect the sound pressure, the abnormal deformation of the curved portion 40a in a case of wearing or removing the headphone can be more suitably suppressed as described above, and the abnormal deformation of the curved portion 40a in a case where the piezoelectric film 40 is subjected to an impact or the curved portion 40a is touched can also be suppressed. On the other hand, as described above, it is necessary to draw out the electrode from the electrode layer of the piezoelectric film to the outside. From the viewpoint of manufacturing, it is desirable to draw out the electrode after forming the curved portion. In addition, from the viewpoint of manufacturing, it is desirable to draw out the electrode by forming a through-hole in the protective layer by a laser or the like and filling the through-hole with a conductive material to draw out the electrode to the outside. In a case where the through-hole is formed in the protective layer by a laser or the like, it is necessary to reduce the thickness of the protective layer from the viewpoint of throughput during manufacturing, quality stability of the through-hole, and the like. In this case, the thickness of the protective layer is preferably 1 μm to 10 μm, and more preferably 3 μm to 6 μm.

As described above, in a case where it is necessary to reduce the thickness of the protective layer, the piezoelectric film 40 has the reinforcing sheet 42, so that the deformation of the curved portion 40a can be more suitably suppressed.

In a case where the piezoelectric film 40 has the reinforcing sheet 42, as the through-hole is formed in the protective layer by a laser or the like, for example, the curved portion 40a is formed in the piezoelectric film 40 having the reinforcing sheet 42, a part of the reinforcing sheet 42 is partially lifted (peeled off and removed) at a peripheral edge portion (see reference numeral 10c in FIG. 5) of the curved portion 40a, the protective layer is subjected to laser processing to form the through-hole, the through-hole is filled with the conductive material, and a lead wire consisting of a metal foil such as Cu is adhered to the conductive material, so that the electrode can be drawn out to the outside. In a process in which the conductive material is dried, favorable adhesiveness is provided between the conductive material and the lead wire.

As described above, in order to make the reinforcing sheet 42 peelable, it is preferable to use a weakly adhesive layer for bonding the reinforcing sheet 42 and the protective layer.

In the example shown in FIG. 20, the reinforcing sheet 42 is configured to be disposed on the convex surface side of the piezoelectric film 40; but the present invention is not limited thereto, and the reinforcing sheet 42 may be disposed on the concave surface side. Alternatively, the reinforcing sheet 42 may be disposed on both surfaces of the piezoelectric film 40.

Here, it is preferable that the headphone according to the embodiment of the present invention further includes a protector ring which is disposed to be in contact with the ear pad between the driver unit and the ear pad, in which the protector ring has an opening portion which penetrates in a direction perpendicular to a surface in contact with the ear pad, the protector ring is in contact with a region of 30% or more of a total area of the ear pad in a case of being viewed in the direction perpendicular to the surface in contact with the ear pad, and a shortest distance between the protector ring and the piezoelectric film of the driver unit is 0.3 mm or more. Such a configuration will be described with reference to FIG. 22.

FIG. 22 is a cross-sectional view conceptually showing another example of the headphone according to the embodiment of the present invention. A headphone 230 shown in FIG. 22 include a housing 202 which forms an outer shell, a driver unit 100 accommodated in the housing 202, an ear pad 204 disposed on a surface side of the driver unit 100 opposite to the housing 202 side, and a protector ring 232 disposed between the ear pad 204 and the driver unit 100. In the example shown in FIG. 22, the housing 202, the driver unit 100, and the ear pad 204 have the same configurations as those in the example shown in FIG. 1, and thus the description thereof will not be repeated. In addition, in FIG. 22, an ear pad locking member is not shown, but the headphone 230 shown in FIG. 22 may also include the ear pad locking member.

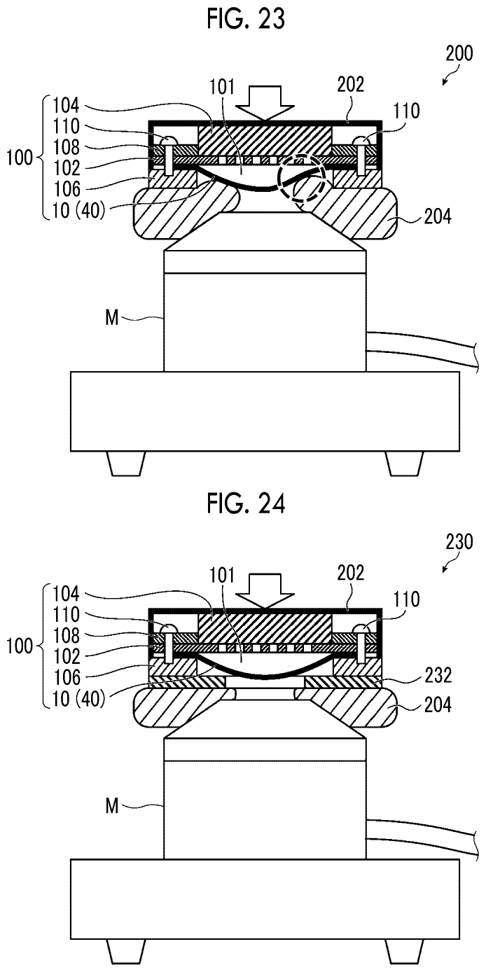

The protector ring 232 is an annular (ring-shaped) plate member having an opening portion. The protector ring 232 is disposed in contact with the ear pad 204 to prevent the ear pad 204 from deforming to the driver unit 100 side and from coming into contact with the piezoelectric film 10 (curved portion 10a) in a case where the user wears the headphone 230. This point will be described with reference to FIGS. 23 and 24.

FIG. 23 is a view showing a state in which the headphone 200 not including the protector ring 232 is pressed against the artificial ear (measurement device) M and is subjected to a load from above. FIG. 24 is a view showing a state in which the headphone 230 including the protector ring 232 is pressed against the artificial ear (measurement device) M and is subjected to a load from above.

As shown in FIG. 23, in a case where the headphone 200 does not include the protector ring 232, the ear pad 204 may deform to the driver unit 100 side due to the shape, the size, and the material of the ear pad 204, a positional relationship between the ear pad 204 and the driver unit 100 (piezoelectric film 10), a pressing force applied to the headphone 200, or the like, and may come into contact with the curved portion 10a of the piezoelectric film 10, which may cause the curved portion 10a to be deformed. In a case where the curved portion 10a is deformed, the sound quality is deteriorated.

On the other hand, as shown in FIG. 24, as the headphone 230 includes the protector ring 232, even in a case where the pressing force is applied to the headphone 200, the ear pad 204 can be prevented from deforming to the driver unit 100 side, and the piezoelectric film 10 (curved portion 10a) can be prevented from coming into contact with the ear pad 204. By preventing the ear pad 204 from coming into contact with the piezoelectric film 10 (curved portion 10a), the abnormal deformation of the curved portion 10a of the piezoelectric film 10 can be prevented, and the deterioration in the sound quality due to the deformation of the curved portion 10a can be prevented. Furthermore, by preventing the ear pad 204 from deforming to the driver unit 100 side, the ear pad 204 is more effectively crushed over a wider area, the air tightness of the space composed of the ear of the user and the ear pad 204 is increased, and thus the sound pressure in the middle and low-frequency ranges can be further improved.

The same effect as that of the protector ring 232 can be obtained even in a headphone including the driver unit which does not have the perforated plate.

In the example shown in FIG. 22, one surface of the protector ring 232 is in contact with the ear pad 204, and the other surface is in contact with the driver unit 100 (holding member 106). The present invention is not limited thereto, and a spacer or the like may be provided between the other surface of the protector ring 232 and the driver unit 100 (holding member 106), or the holding member 106 may also serve as the spacer. By providing the spacer or by having the holding member 106 also serve as the spacer, a distance between the protector ring 232 and the piezoelectric film 10, that is, a distance between the ear pad 204 and the piezoelectric film 10 can be appropriately adjusted. Furthermore, a component in which the protector ring 232 and the holding member 106 are integrated may be used. In addition, although not shown in FIG. 22, the locking member 206 may have the function of the protector ring 232, and a component in which the holding member 106 is further integrated may be used.

In addition, it is preferable that the protector ring 232 is in contact with a region of 30% or more of the total area of the ear pad in a case of being viewed in the direction perpendicular to the surface in contact with the ear pad 204. This point will be described with reference to FIG. 25.

FIG. 25 is a view showing the ear pad 204 and the protector ring 232 as viewed in the direction perpendicular to the surface of the protector ring 232 in contact with the ear pad 204 (viewed from a left-right direction of FIG. 22).

In FIG. 25, a region indicated by hatching inclined to the right is the ear pad 204, and a region in which hatching inclined to the left and hatching inclined to the right overlap is a region in which the ear pad 204 and the protector ring 232 are in contact with each other. That is, a proportion of an area of the region in which the hatching inclined to the left and the hatching inclined to the right overlap (an area of the region in which the protector ring 232 and the ear pad 204 are in contact with each other) to an area of the region indicated by the hatching inclined to the right (the total area of the ear pad 204) is preferably 30% or more, more preferably 50% or more, and still more preferably 70% or more.

As a result, in a case where the user wears the headphone 230, the ear pad 204 can be prevented from deforming to the driver unit 100 side, the ear pad 204 can be prevented from coming into contact with the piezoelectric film 10, and thus the abnormal deformation of the curved portion 10a of the piezoelectric film 10 can be prevented.

In addition, the shortest distance t (see an enlarged view of FIG. 22) between the protector ring 232 and the piezoelectric film 10 of the driver unit 100 is preferably 0.3 mm or more, more preferably 0.5 mm or more, and still more preferably 1 mm or more. The shortest distance t between the protector ring 232 and the piezoelectric film 10 is a distance in a case where the piezoelectric film 10 is not driven.

As a result, even in a case where the piezoelectric film 10 is driven and vibrates, the protector ring 232 can be prevented from coming into contact with the piezoelectric film 10. In addition, in a case where the user wears the headphone 230, the ear pad 204 can be prevented from deforming to the driver unit 100 side, the ear pad 204 can be prevented from coming into contact with the piezoelectric film 10, and thus the abnormal deformation of the curved portion 10a of the piezoelectric film 10 can be prevented.

In addition, an inner diameter of the protector ring 232 (a diameter of the opening portion) may be larger than, smaller than, or substantially the same as the inner diameter of the ear pad 204. The inner diameter of the protector ring 232 is preferably approximately −10 mm to +10 mm with respect to the inner diameter of the ear pad 204.

In addition, a thickness of the protector ring 232 is not particularly limited, but from the viewpoint of preventing the deformation of the protector ring 232 in a case where the ear pad 204 is pressed, size reduction of the headphone 230, and the like, it is preferably 0.5 mm to 10 mm, more preferably 1 mm to 7 mm, and still more preferably 2 mm to 5 mm.

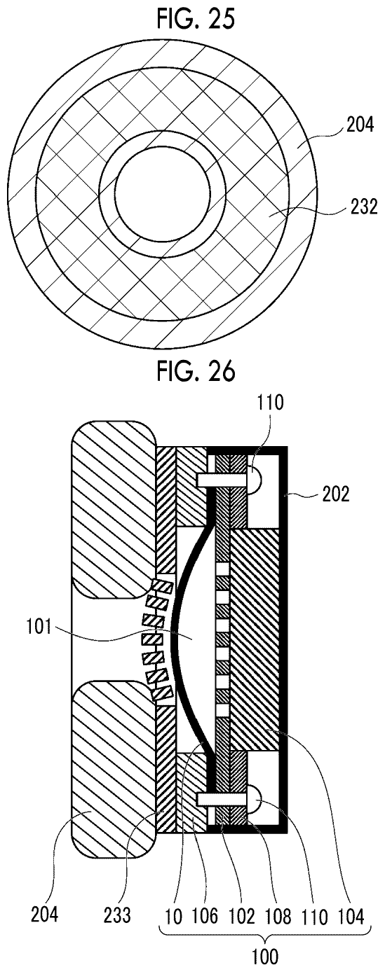

In addition, a grille may be provided in the opening portion of the protector ring, or a protector ring integrated with the grille may be used. FIG. 26 is a cross-sectional view conceptually showing another example of the headphone according to the embodiment of the present invention. The headphone shown in FIG. 26 has the same configuration as the headphone shown in FIG. 22, except that a protector ring 233 is provided instead of the protector ring 232.

The protector ring 233 has a grille-shaped portion in which a plurality of holes are formed in a central portion, that is, directly below a central hole of the ear pad 204. As a result, it is possible to prevent the piezoelectric film 10 from being physically touched by a finger or the like and abnormally deformed, while transmitting the sound to the ear.

It is desirable that a contact surface of the protector ring 233 with the ear pad 204 is flat, but in order to ensure the shortest distance t between the protector ring 233 and the piezoelectric film 10 to be 0.3 mm or more, the central portion (grille portion) may be curved as necessary as shown in FIG. 26.

The driver unit and the headphone according to the embodiment of the present invention have been described in detail above, but the present invention is not limited to the above-described examples, and various improvements and changes may be made without departing from the spirit of the present invention.

### EXAMPLES

Hereinafter, the present invention will be described in more detail with reference to specific examples of the present invention. The present invention is not limited to the examples, and the materials, the used amounts, the proportions, the treatment contents, the treatment procedures, and the like shown in the following examples can be appropriately changed within a range not departing from the scope of the present invention.

### Example 1

### <Production of Piezoelectric Film>

A piezoelectric film was produced by the method shown in FIGS. 11 to 13 described above.

First, cyanoethylated PVA (CR-V manufactured by Shin-Etsu Chemical Co., Ltd.) was dissolved in dimethylformamide (DMF) at the following compositional ratio. Thereafter, PZT particles as piezoelectric particles were added to the solution at the following compositional ratio, and the solution was stirred using a propeller mixer (rotation speed: 2000 rpm), thereby preparing a coating material for forming a piezoelectric layer.
PZT Particles: 300 parts by mass
Cyanoethylated PVA: 30 parts by mass
DMF: 70 parts by mass

Particles obtained by sintering commercially available PZT raw material powder at 1000° C. to 1200° C. and then crushing and classifying the sintered powder to have an average particle diameter of 2 μm were used as the PZT particles.

On the other hand, sheet-like materials 11a and 11b obtained by performing vacuum vapor deposition on a copper thin film having a thickness of 0.1 μm were prepared on a PET film having a thickness of 4 μm. That is, in the present example, the first electrode layer and the second electrode layer were copper-deposited thin films having a thickness of 0.3 μm, and the first protective layer and the second protective layer were PET films having a thickness of 4 μm. In order to obtain favorable handleability during the process, a film with a separator (temporary support, PET) having a thickness of 50 μm was used as the PET film, and the separator of each protective layer was removed after the thermal compression bonding of the sheet-like material 11c.

The first electrode layer (copper-deposited thin film) of the sheet-like material 11a was coated with the coating material for forming a piezoelectric layer, which was prepared in advance, using a slide coater. The coating material was applied so that a film thickness of the coating film after drying was 50 μm.

Next, the material obtained by coating the sheet-like material with the coating material was heated and dried on a hot plate at 120° C. to evaporate DMF. In this manner, a piezoelectric laminate 11b in which the first electrode layer made of copper was provided on the first protective layer made of PET and the piezoelectric layer (polymer-based piezoelectric composite material layer) having a thickness of 50 μm was formed thereon was produced.

The produced piezoelectric layer was subjected to a polarization treatment in the thickness direction.

A sheet-like material 11c obtained by vapor-depositing a copper thin film on the PET film was laminated on the piezoelectric laminate subjected to the polarization treatment such that the second electrode layer (copper thin film side) faced the piezoelectric layer.

Next, the laminate of the piezoelectric laminate and the sheet-like material was subjected to thermal compression bonding at a temperature of 120° C. using a laminator device to adhere the piezoelectric layer and the second electrode layer by bonding, thereby producing a piezoelectric film as shown in FIG. 10.

Next, the produced piezoelectric film was formed into a shape having the curved portion 10a as shown in FIG. 1 by a heating compression molding method using a mold having a shape corresponding to the shape of the curved portion 10a to be formed and a hot press device (AH-2003 manufactured by AS ONE Corporation). The shape of the curved portion 10a was a shape consisting of a part of a sphere. In addition, the shape of the curved portion 10a as viewed in a direction perpendicular to a main surface of the piezoelectric film was circular, and a diameter was 60 mm and a height was 5 mm.

Thereafter, the curved portion 10a was cut out to have a diameter of 64 mm.

In this manner, a piezoelectric film 10 having a curved portion was produced.

### <Production of Driver Unit>

As a perforated plate, a copper plate having a thickness of 100 μm was prepared. The copper plate was cut out to have a diameter of 86 mm, and 13 through-holes having a diameter of 4 mm were formed in a staggered manner at a substantially central portion thereof (see FIG. 2). The total area of the through-holes was 6% of the area of a vibration region (curved portion) of the piezoelectric film. In addition, 8 insertion holes were provided at equal intervals in a circumferential direction in a vicinity of an end portion.

Two acrylic plates having a thickness of 3 mm were cut out into a ring shape with an outer diameter of 86 mm and an inner diameter of 60 mm, and used as two holding members. On one holding member, 8 insertion holes were provided at equal intervals in a circumferential direction in a vicinity of the end portion. On the other holding member, 8 screw holes were provided at equal intervals in the circumferential direction in a vicinity of the end portion.

The holding member having the screw holes, the piezoelectric film, the perforated plate, and the holding member having the insertion holes were stacked in this order, and a screw as a fastening member was inserted into the insertion hole from the holding member side on the perforated plate side to be screwed into the screw hole of the holding member on the piezoelectric film side, whereby the piezoelectric film and the perforated plate were sandwiched between the two holding members. The perforated plate was laminated on the concave surface side of the curved portion of the piezoelectric film.

As a porous material, urethane foam (UBTK manufactured by Bridgestone Corporation) having a thickness of 15 mm was cut out to have a diameter of 60 mm. The porous material was installed on a surface of the perforated plate on the holding member side to produce a driver unit. The porous material was bonded to the perforated plate with an adhesive. In this case, the adhesive did not block the through-hole.

### Comparative Example 1

A driver unit was produced in the same manner as in Example 1, except that the perforated plate and the porous material were not provided.

### Evaluation

The produced driver unit of Example or Comparative Example was accommodated in a housing, and an ear pad was disposed on the opening portion side of the housing to produce a test unit which simulated a headphone.

The driver unit was disposed in the opening portion of the housing such that the concave surface of the curved portion was on the housing side, and the ear pad was disposed on the side of the driver unit opposite to the housing to produce a test unit. In this case, a gap was provided between the driver unit and the housing, and a second air chamber defined by the driver unit and the housing was configured to communicate with the outside.

The produced test unit was placed on an artificial ear (TYPE2015E manufactured by ACO CO., LTD.) for headphone measurement without load on the ear pad side, and a sine sweep signal with a frequency of 20 Hz to 20 kHz and an applied voltage of 10 Vpp was input to the piezoelectric film to measure a sound pressure. Next, the test unit was pressed against the artificial ear for headphone measurement with a pressing force of 200 g, and a sine sweep signal with a frequency of 20 Hz to 20 kHz and an applied voltage of 10 Vpp was input to the piezoelectric film to measure a sound pressure.

Graphs of frequency characteristics of Example 1 and Comparative Example 1 are shown in FIGS. 15 and 16, respectively.

As shown in FIG. 16, in Comparative Example 1, it was found that a peak or dip occurred in the sound pressure in the high-frequency range, and a ripple occurred in the frequency characteristic.

In addition, as shown by a broken line in FIG. 16, in a case of being pressed against a coupler with a load, it was found that the sound pressure in the low-frequency range was lower than the sound pressure in the middle and high-frequency ranges. In a case where the piezoelectric film was observed after the test, the shape of the curved portion was deformed. It is considered that, in a case where the test unit was pressed against the coupler, a pressure difference occurred between the coupler side of the piezoelectric film and the side of the piezoelectric film opposite to the coupler side, the shape of the curved portion was deformed, and the frequency characteristic was changed due to this.

On the other hand, it was found that Example 1 shown in FIG. 15 could achieve a flat frequency characteristic in which the sound pressure did not change in a wide frequency band from the low-frequency range to the high-frequency range. In addition, it was found that the change in the frequency characteristic between with and without the load was small. In a case where the piezoelectric film was observed after the test, no deformation of the curved portion was observed.

### Example 2

A driver unit was produced in the same manner as in Example 1, except that a series resistor (360Ω) was connected to a wiring connected to the electrode layers of the piezoelectric film.

The produced test unit was placed on an artificial ear (TYPE2015E manufactured by ACO CO., LTD.) for headphone measurement without load on the ear pad side, and a sine sweep signal with a frequency of 20 Hz to 20 kHz and an applied voltage of 10 Vpp was input to the piezoelectric film to measure a sound pressure.

FIG. 17 shows measurement results of frequency characteristics of Example 1 and Example 2 without load.

As shown in FIG. 17, in a case where there was no resistor between the piezoelectric film and the signal source (Example 1), the sound pressure in a frequency band of 1.0 kHz or more was slightly higher than the sound pressure in a frequency band of less than 1.0 kHz, but in Example 2 in which the resistor was connected in series between the piezoelectric film and the signal source, the sound pressure in the frequency band of 1.0 kHz or more could be reduced, and thus the frequency characteristic could be made flatter.

### Example 2B to Example 2D

Test units were produced in the same manner as in Example 2, except that the resistance values of the series resistors of Examples 2B to 2D were changed to 100 Ω, 200Ω, and 400Ω, respectively, and then the frequency characteristics were measured.

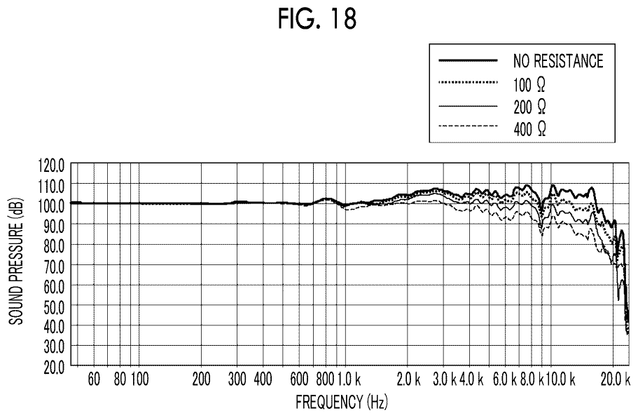

The results are shown in FIG. 18.

As shown in FIG. 18, in a case where there was no resistor between the piezoelectric film and the signal source, the sound pressure in a frequency band of 1.0 kHz or more was slightly higher than the sound pressure in a frequency band of less than 1.0 kHz, but by connecting the resistor in series between the piezoelectric film and the signal source, the sound pressure in the frequency band of 1.0 kHz or more could be reduced, and thus the frequency characteristic could be made flatter. In addition, it was found that, by the resistance value to be connected, the sound pressure in the frequency band of 1.0 kHz or more could be adjusted without affecting the sound pressure in the frequency band of less than 1.0 kHz.

### Example 3

In Example 1, in a case of producing the piezoelectric film, a curved portion 40a was formed without removing one of the separators made of PET having a thickness of 50 μm, after the lamination of the sheet-like material 11c (see FIG. 13). This separator was used as a reinforcing sheet 42. The curved portion 40a was formed such that the reinforcing sheet 42 side was a convex surface. The shape of the curved portion 40a was a shape consisting of a part of a sphere. In addition, the shape of the curved portion 40a as viewed in a direction perpendicular to a main surface of the piezoelectric film was circular, and a diameter was 60 mm and a height was 5 mm.

Thereafter, the curved portion 40a was cut out to have a diameter of 70 mm.

In this manner, a piezoelectric film 40 having the PET film having a thickness of 50 μm as the reinforcing sheet 42, and having the curved portion 40a was produced.

A driver unit was produced in the same manner as in Example 1 using the produced piezoelectric film 40.

### Example 4

A piezoelectric film 40 was produced and a driver unit was produced in the same manner as in Example 3, except that a separator made of PET having a thickness of 25 μm was used as the reinforcing sheet 42.

### Example 5

A piezoelectric film 40 was produced and a driver unit was produced in the same manner as in Example 3, except that a nonwoven fabric (Japanese paper) having a thickness of 15 μm was used as the reinforcing sheet 42 to produce the piezoelectric film 40 as follows.

In a case of producing the piezoelectric film, two separators were removed after the lamination of the sheet-like material 11c, the nonwoven fabric (Japanese paper) having a thickness of 15 μm was bonded to one protective layer, and the curved portion 40a was formed to produce the piezoelectric film. A hot melt sheet having a thickness of 12 μm was used for bonding the nonwoven fabric (Japanese paper).

### Example 6

A piezoelectric film 40 was produced and a driver unit was produced in the same manner as in Example 5, except that a nonwoven fabric (Japanese paper) having a thickness of 40 μm was used as the reinforcing sheet 42.

### Example 7

A piezoelectric film 40 was produced and a driver unit was produced in the same manner as in Example 5, except that a woven fabric (cheesecloth) having a thickness of 50 μm was used as the reinforcing sheet 42.

### Reference Examples 1 to 5

As Reference Examples 1 to 5, driver units were produced in the same manner as in Examples 3 to 7, except that the perforated plate and the porous material were not provided.

### Evaluation

The convex surface of the curved portion of the driver units produced in Examples 1, 3 to 7, Comparative Example 1, and Reference Examples 1 to 5 was placed on a transparent acrylic plate with the ear pad facing down in a state in which the ear pad was mounted, and were subjected to a load from above. The state of the curved portion of the piezoelectric film was observed from below the acrylic plate under each of loads of 100 g, 200 g, 300 g, 400 g, 500 g, and 600 g. In a case where there was no deformation, it was indicated as A, and in a case where there was deformation, it was indicated as C.

The results are shown in Table 2.

TABLE 2

| | Reinforcing sheet | | Perforated plate + porous | Evaluation | | | | | |
|---|---|---|---|---|---|---|---|---|---|
| | Type | Thickness | material | 100 g | 200 g | 300 g | 400 g | 500 g | 600 g |
| Comparative | None | — | N | A | C | C | C | C | C |
| Example 1 | | | | | | | | | |
| Example 1 | None | — | Y | A | A | A | A | A | C |
| Reference Example | PET | 50 μm | N | A | A | A | A | C | C |
| 1 | | | | | | | | | |
| Example 3 | PET | 50 μm | Y | A | A | A | A | A | A |
| Reference Example | PET | 25 μm | N | A | A | A | C | C | C |
| 2 | | | | | | | | | |
| Example 4 | PET | 25 μm | Y | A | A | A | A | A | A |
| Reference Example | Nonwoven | 15 μm | N | A | A | A | C | C | C |
| 3 | fabric | | | | | | | | |
| Example 5 | Nonwoven | 15 μm | Y | A | A | A | A | A | A |
| | farbic | | | | | | | | |
| Reference Example | Nonwoven | 40 μm | N | A | A | A | A | A | C |
| 4 | fabric | | | | | | | | |
| Example 6 | Nonwoven | 40 μm | Y | A | A | A | A | A | A |
| | fabric | | | | | | | | |
| Reference Example | Woven fabric | 50 μm | N | A | A | A | A | A | C |
| 5 | | | | | | | | | |
| Example 7 | Woven fabric | 50 μm | Y | A | A | A | A | A | A |

From Table 2, it was found that Examples 3 to 7 having the reinforcing sheet could more suitably suppress the abnormal deformation of the curved portion as compared with Example 1 having no reinforcing sheet. In addition, from the comparison between Comparative Example 1 and Reference Examples 1 to 5, it was found that the abnormal deformation of the curved portion could be more suitably suppressed by having the reinforcing sheet.

The pressing force applied in a case of wearing general headphones is approximately 200 g to 400 g.

### Example 8

The driver unit of Example 1 was accommodated in a housing, the following protector ring was disposed on the opening portion side of the housing, and the ear pad was disposed to be in contact with the protector ring to produce a test unit which simulated a headphone.

The protector ring was produced by cutting out an acrylic plate having a thickness of 3 mm into a ring shape with an outer diameter of 74 mm and an inner diameter of 40 mm.

In the produced test unit, the shortest distance t between the protector ring and the piezoelectric film was 1 mm. In addition, the protector ring was in contact with a region of 85% of the total area of the ear pad as viewed in the direction perpendicular to the surface in contact with the ear pad. The ear pad had an inner diameter of approximately 32 mm, an outer diameter of approximately 72 mm, and a thickness of approximately 15 mm.

### Evaluation

First, the test unit produced in Example 1 was placed on an artificial ear (TYPE2015E manufactured by ACO CO., LTD.) for headphone measurement with a load of 200 g or 500 g on the ear pad side, and a sine sweep signal with a frequency of 20 Hz to 20 kHz and an applied voltage of 10 Vpp was input to the piezoelectric film to measure a sound pressure.

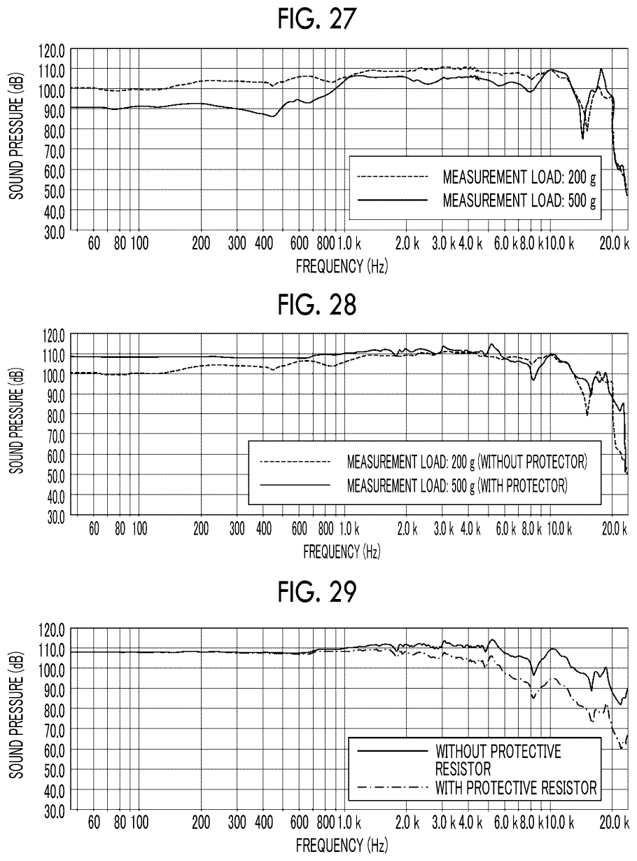

FIG. 27 shows a graph of the frequency characteristic.

As shown in FIG. 27, in a case of the load of 500 g, the sound pressure in the low-frequency range was particularly reduced as compared with a case of the load of 200 g. It is considered that this is because, in a case where the test unit was pressed against the artificial ear, the ear pad was deformed and came into contact with the piezoelectric film.

Next, the test unit produced in Example 8 was placed on an artificial ear (TYPE2015E manufactured by ACO CO., LTD.) for headphone measurement with a load of 500 g on the ear pad side, and a sine sweep signal with a frequency of 20 Hz to 20 kHz and an applied voltage of 10 Vpp was input to the piezoelectric film to measure a sound pressure.

FIG. 28 shows a graph of the frequency characteristic. In addition, the result of Example 1 with the load of 200 g is also shown.

As shown in FIG. 28, it was found that the test unit of Example 8 having the protector ring did not cause a decrease in the sound pressure even in a case of being pressed against the artificial ear with the load of 500 g. In addition, as compared with the result of Example 1 with the load of 200 g, in Example 8, the sound pressure in the middle and low-frequency ranges was improved. It is considered that this is because, by having the protector ring, the deformation of the ear pad to the driver unit side was prevented, and air tightness between the artificial ear and the space in the ear pad was increased by effectively crushing the ear pad over a wider area, so that the sound pressure in the middle and low-frequency ranges was further improved.

### Example 8B

A driver unit was produced in the same manner as in Example 8, except that a series resistor (360Ω) was connected to the wiring connected to the electrode layer of the piezoelectric film.

The produced test unit was placed on an artificial ear (TYPE2015E manufactured by ACO CO., LTD.) for headphone measurement with a load of 400 g on the ear pad side, and a sine sweep signal with a frequency of 20 Hz to 20 kHz and an applied voltage of 10 Vpp was input to the piezoelectric film to measure a sound pressure.

FIG. 29 shows measurement results of frequency characteristics of Examples 8 and 8B.

From the results of FIG. 29, it was found that Example 8B in which the resistor was connected in series between the piezoelectric film and the signal source could reduce the sound pressure in the frequency band of 1.0 kHz or more and thus could make the frequency characteristic flatter.

From the above, the effects of the present invention are clear.

### EXPLANATION OF REFERENCES

10: piezoelectric film
10a: curved portion
10c: edge portion
11a, 11c: sheet-like material
11b: piezoelectric laminate
20: piezoelectric layer
24: first electrode layer
26: second electrode layer
28: first protective layer
30: second protective layer
34: matrix
36: piezoelectric particle
40: piezoelectric film
40a: curved portion
42: reinforcing sheet
44: pressure-sensitive adhesive layer
100, 100b: driver unit
101: first air chamber
102: perforated plate
102a: through-hole
102b: insertion hole
104: porous material
106: holding member
106a: screw hole
108: holding member
108a: insertion hole
110: fastening member
200, 200b: headphone
201: second air chamber
202: housing
202a: through-hole
204: ear pad
206: ear pad locking member
220: signal source
222: resistor
230: headphone
232: protector ring
U: ear of user
M: measuring device (artificial ear)

What is claimed is:

1. A driver unit comprising:
a piezoelectric film which has a piezoelectric layer consisting of a polymer-based piezoelectric composite material containing piezoelectric particles in a matrix containing a polymer material and electrode layers provided on both surfaces of the piezoelectric layer; and
a plate-shaped perforated plate having at least one through-hole,
wherein the piezoelectric film has a curved portion which is formed to protrude to one main surface side and to be recessed to the other main surface side,
the perforated plate is laminated on a concave surface side of the curved portion of the piezoelectric film, and
in the through-hole, a first air chamber defined by the concave surface of the piezoelectric film and the perforated plate communicates with an outside.

2. The driver unit according to claim 1,
wherein a proportion of a total area of the through-holes to an area of the curved portion of the piezoelectric film in a plan view is 3% to 70%.

3. The driver unit according to claim 1, further comprising:
an acoustic absorption layer consisting of a porous material which is disposed to cover the through-hole on a surface of the perforated plate opposite to the piezoelectric film.

4. The driver unit according to claim 1,
wherein a shape formed by a boundary line of the curved portion of the piezoelectric film is circular.

5. The driver unit according to claim 1, further comprising:
a series resistor connected between the electrode layers of the piezoelectric film and a signal source which drives the piezoelectric film.

6. A headphone comprising:
the driver unit according to claim 1;
a housing which has an opening portion and accommodates the driver unit; and
an ear pad which is disposed on an opening portion side of the housing.

7. The headphone according to claim 6,
wherein a second air chamber defined by the driver unit and the housing communicates with an outside.

8. The headphone according to claim 6,
wherein the housing is disposed on the concave surface side of the piezoelectric film of the driver unit.

9. The headphone according to claim 6, further comprising:
a protector ring which is disposed to be in contact with the ear pad between the driver unit and the ear pad,
wherein the protector ring has an opening portion which penetrates in a direction perpendicular to a surface in contact with the ear pad,
the protector ring is in contact with a region of 30% or more of a total area of the ear pad in a case of being viewed in the direction perpendicular to the surface in contact with the ear pad, and
a shortest distance between the protector ring and the piezoelectric film of the driver unit is 0.3 mm or more.

10. The driver unit according to claim 2, further comprising:
an acoustic absorption layer consisting of a porous material which is disposed to cover the through-hole on a surface of the perforated plate opposite to the piezoelectric film.

11. The driver unit according to claim 2,
wherein a shape formed by a boundary line of the curved portion of the piezoelectric film is circular.

12. The driver unit according to claim 2, further comprising:
a series resistor connected between the electrode layers of the piezoelectric film and a signal source which drives the piezoelectric film.

13. A headphone comprising:
the driver unit according to claim 2;
a housing which has an opening portion and accommodates the driver unit; and
an ear pad which is disposed on an opening portion side of the housing.

14. The headphone according to claim 13,
wherein a second air chamber defined by the driver unit and the housing communicates with an outside.

15. The headphone according to claim 7,
wherein the housing is disposed on the concave surface side of the piezoelectric film of the driver unit.

16. The headphone according to claim 13, further comprising:
a protector ring which is disposed to be in contact with the ear pad between the driver unit and the ear pad,
wherein the protector ring has an opening portion which penetrates in a direction perpendicular to a surface in contact with the ear pad,
the protector ring is in contact with a region of 30% or more of a total area of the ear pad in a case of being viewed in the direction perpendicular to the surface in contact with the ear pad, and
a shortest distance between the protector ring and the piezoelectric film of the driver unit is 0.3 mm or more.

17. The driver unit according to claim 3,
wherein a shape formed by a boundary line of the curved portion of the piezoelectric film is circular.

18. The driver unit according to claim 3, further comprising:
a series resistor connected between the electrode layers of the piezoelectric film and a signal source which drives the piezoelectric film.

19. A headphone comprising:
the driver unit according to claim 3;
a housing which has an opening portion and accommodates the driver unit; and
an ear pad which is disposed on an opening portion side of the housing.

20. The headphone according to claim 19,
wherein a second air chamber defined by the driver unit and the housing communicates with an outside.
